(19) United States
(12) Patent Application Publication
(10) Pub. No.: US 2014/0103985 A1
(43) Pub. Date: Apr. 17, 2014

(54) Digitally Controlled Delay Line for a Structured ASIC Having a Via Configurable Fabric for High-Speed Interface

(71) Applicant: eASIC Corporation, (US)

(72) Inventors: Alexander Andreev, San Jose, CA (US); Sergey Gribok, Santa Clara, CA (US); Marian Serban, Santa Clara, CA (US); Massimo Verita, Pleasanton, CA (US); Kee-Wei Sim, Bayan Baru (MY); Kok-Hin Lew, Bayan Baru (MY)

(73) Assignee: EASIC CORPORATION, Santa Clara, CA (US)

(21) Appl. No.: 13/649,584

(22) Filed: Oct. 11, 2012

(51) Int. Cl. H03H 17/00

(52) U.S. Cl. CPC H03H 17/0009
USPC 327/262

(57) ABSTRACT

A Digitally Controlled Delay Line (DCDL) for a Structured ASIC chip is used to delaying input or output signals into or out of core logic in a Structured ASIC. The DCDL has a multi-stage configuration that in a preferred embodiment comprises two fine delay stages for fine tuning the delay using sub-gate delay through an inverter whose delay can be adjusted with parallel CMOS transistors whose gates are biased with a voltage control signal that is thermometer coded. The fine-tune stages are followed by coarse delay stages that use gate-level delay. A DCDL controller outputs control signals that are Grey coded and converted to thermometer coded control signals by a Binary-to-Thermometer Decoder. The DCDL circuit block and accompanying Structured ASIC are manufactured on a 28 nm CMOS process lithographic node or smaller. A high speed routing fabric using a balanced binary tree is employed with the DCDL.

### CROSS-REFERENCE TO RELATED APPLICATIONS

The present application is related to: U.S. application Ser. No. ______, Attn. Docket No. EAS 12-1-2 for “VIA-CONFIGURABLE HIGH-PERFORMANCE LOGIC BLOCK INVOLVING TRANSISTOR CHAINS” by Alexander Andreev, Sergey Gribok, Ranko Scepanovic, Phey-Chuin TAN, Chee-Wei KUNG, filed the same day as the present invention, ______ 2012; U.S. application Ser. No. ______, Attn. Docket No. EAS 12-2-2 for “ARCHITECTURAL FLOORPLAN FOR A STRUCTURED ASIC MANUFACTURED ON A 28 NM CMOS PROCESS LITHOGRAPHIC NODE OR SMALLER” by Alexander Andreev, Ranko Scepanovic, Ivan Pavisic, Alexander Yahontov, Mikhail Udovikhin, Igor Vikhliantsev, Chong-Teik LIM, Seow-Sung LEE, Chee-Wei KUNG, filed the same day as the present invention, ______ 2012; U.S. application Ser. No. ______, Attn. Docket No. EAS 12-3-2 for “CLOCK NETWORK FISHBONE ARCHITECTURE FOR A STRUCTURED ASIC MANUFACTURED ON A 28 NM CMOS PROCESS LITHOGRAPHIC NODE” by Alexander Andreev, Andrey Nikishin, Sergey Gribok, Phey-Chuin TAN, Choon-Hun CHOO, filed the same day as the present invention, ______ 2012; U.S. application Ser. No. ______, Attn. Docket No. EAS 12-4-2 for “MICROCONTROLLER CONTROLLED OR DIRECT MODE CONTROLLED NETWORK-FABRIC ON A STRUCTURED ASIC” by Alexander Andreev, Andrey Nikitin, Marian Serbian, Massimo Verita, filed the same day as the present invention, ______ 2012; Attn. Docket No. EAS 12-5-2 for “TEMPERATURE CONTROLLED STRUCTURED ASIC MANUFACTURED ON A 28 NM CMOS PROCESS LITHOGRAPHIC NODE” by Alexander Andreev and Massimo Verita, filed the same day as the present invention, ______ 2012; and all assigned to the same Assignee as the present invention, all of which are specifically incorporated herein by reference.

### BACKGROUND OF THE INVENTION

1. Field of Invention

The present invention relates generally to the field of Structured ASICs. Embodiments of the present invention relate to a circuit for a Structured ASIC.

2. Description of Related Art

The present invention relates generally to an improved Digitally Controlled Delay Line (DCDL) for a Structured ASIC.

A Structured ASIC is an ASIC (Application-Specific Integrated Circuit) having some pre-made elements that are manufactured once in a first manufacturing process and kept in inventory, then the elements are interconnected later, or customized by a customer, in a second manufacturing process by masks (mask-programmable) rather than making a circuit all at once as in a traditional ASIC. In a Structured ASIC the customization occurs by configuring one or more via layers between metal layers in the ASIC.

A configurable logic block (CLB) may be an element of field-programmable gate array (FPGA), structured ASIC devices, and/or other devices. CLBs may be configured, for example, to implement different random logic (from combinational logic, such as NANDs, NORs, or inverters, and/or sequential logic, such as flip-flops or latches).

Broadly defined, structured application-specific integrated circuits (ASICs) may attempt to reduce the effort, expense and risk of producing ASICs by standardizing portions of the physical implementation across multiple products. By amortizing the expensive mask layers of the device across a large set of different designs, the non-recurring engineering (NRE) for a customized ASIC seen by a particular customer, which are one-time costs that do not depend on the number of units sold, can be significantly reduced. There may be additional benefits to the standardization of some portion of mask set, which may include improved yield through higher regularity and/or reduced manufacturing time from tape-out to packaged chip.

ASICs can be broken down further into a full-custom ASIC, a Standard Cell-based ASIC (standard-cell), and a gate array ASIC. At the opposite end of an ASIC is a field-programmable gate array (FPGA), an integrated circuit designed to be configured by the customer or designer after manufacturing in the field using software commands rather than at a foundry or IC fab. Other non-ASICs include simple and complex PLDs (Programmable Logic Devices), and off-the-shelf small and medium scale IC components (SSI/MSI).

A full-custom ASIC customizes every layer in an ASIC device, which can have 10 to 15 layers, requiring in a lithography process 10 to 15 masks. Since the customized design of the ASIC occurs at the transistor level, and modern ASICs have tens if not hundreds of millions of transistors, a full-custom ASIC is typically economically feasible only for applications that required millions of units. An example of such an application is the cell phone digital modem or a flat panel television video processing device.

In a standard cell ASIC, circuits are constructed from predefined logic components known as cells. Designers work at the gate level, not the finer transistor level, simplifying the process, and instead of 10-15 layers only 3-5 layers may exist. The fab manufacturing the device provides a library of basic building blocks that can be used in the cells, such as basic logic gates, combinational components (and-or-inverter, multiplexer, 1-bit full adder), and basic memory, such as D-type latch and flip-flop. A library of other function blocks such as adder, barrel shifter and random access memory (RAM) may also exist. While the layout of each cell in a standard cell is predetermined, the circuit itself has to be uniquely constructed by connecting all layers to one another and the cells within each layer in a custom manner, which takes time and effort.

A register is a standard component in an ASIC, and is a group of flip-flops that stores a bit pattern. Registers can hold information from components or hold state between iterations of a clock so that it can be accessed by other components, to allow I/O synchronization, handshaking data between clock domains, pipelining, and the like.

In a gate-array ASIC, the level of abstraction is one level higher than a standard cell, in that each building block in a gate array is from an array of predefined cells, known as a base cell, which resembles a logic gate. Since location and type of cell is predetermined, gate-array ASICs can be manufactured in advance in greater quantities and inventoried for use later. A circuit is manufactured by customizing the interconnect between these cells, which is done at the metal layer via masks. In gate level ASICs, typically fewer metal layers have to be customized to specify the interconnect required to complete the circuit, which simplifies the manufacturing process.

A synchronous digital system has a clock distribution network that defines a reference point for moving data within the system. A clock distribution network distributes the clock signals from a common point to all the elements in the system that need it. Generally clock signals are loaded with a great fanout, travel over comparatively great distances, and operate at the higher speeds than other signals within the synchronous system. Clock waveforms must be particularly clean and sharp. In addition, long global interconnect lines become significantly more resistive as line dimensions are decreased, and is one of the primary reasons for the increasing significance of clock distribution on synchronous performance. The control of any differences and uncertainty in the arrival times of the clock signals can limit the maximum performance of the entire system and create race conditions in which an incorrect data signal may latch within a register. The clock distribution network often takes a significant portion of the power consumed by a chip; furthermore, significant power can be wasted in transitions within blocks, when their output is not needed. Power may be saved by clock gating, which involves adding logic gates to the clock distribution tree, so portions of the tree can be turned off when not needed.

A complex field programmable device is the most versatile non-ASIC, as the generic logic cells can be more sophisticated than ASIC cells, and the interconnect structure can be programmable in the field using software, rather than at a fab using for example photolithographic masks. A complex field programmable device can be re-programmed to a different circuit in hours, rather than only being programmable once at a fab like an ASIC. A complex field programmable device can be broadly divided into two categories, a Complex Programmable Logic Device (CPLD) and a Field Programmable Gate Array (FPGA). The logic cell of a CPLD is more complex than an FPGA, and has a D-type flip-flop and a programmable logic device semiconductor such as a PAL™ type programmable logic device semiconductor, with configurable product terms. The interconnect of a CPLD is more centralized, with fewer concentrated routing lines. A FPGA logic cell is smaller, with a D-type flip-flop and a small Look Up Table (LUT), a multi input and single output block that is widely used for logic mapping, or multiplexers for routing signals through the interconnect and logic cells. The interconnect structure in an FPGA tends to be more distributed and flexible than a CPLD, making it more ideal for more high capacity, complex devices. The FPGA design that defines a circuit is stored in RAM, so when the FPGA is powered off, the design for the circuit disappears. When the FPGA is powered back up, one must reload the circuit design from non-volatile memory.

A simple PLD, historically called a programmable logic device, is much more limited in application, as they do not have a general interconnect structure. Today these devices are relatively rare by themselves and are now used as internal components in an ASIC or CPLD. Likewise, off-the-shelf small and medium scale IC components (SSI/MSI) are rarely used anymore, as they are first generation devices such as the 7400 series transistor-transistor logic (TTL) manufactured by various companies used in the 1960s and 70s to build computers. These components are no longer supported by modern EDA (Electronic Design Automation) software and have very limited functionality.

A complex field programmable device can be thought of as a form of programmable logic fabric. One such programmable logic fabric is a SRAM programmable Look-Up Table (LUT) technology that forms the basis of Field Programmable Gate Arrays and Complex Programmable Logic Devices. The programmable fabric technology allows synthesis of a logic design described in a Hardware Description Language (HDL) to be synthesized on to the logic fabric in order to perform the required logic function. The logic fabric includes memory blocks, embedded multipliers, registers and Look-Up Table logic blocks. Interconnect between logic elements is also SRAM programmable. As the state of the SRAM is deleted when powered off, the function of the programmable logic fabric incorporating SRAM can be changed.

ASIC design flow as a whole is a complex endeavor that involves many tasks, as described further herein, such as: logic synthesis, Design-for-Test (DFT) insertion, Electric Rules Check (ERC) on gate-level netlist, floorplan, die size, I/O structure, design partition, macro placement, power distribution structure, clocks distribution structure, preliminary check, (e.g., IR drop voltage drop, Electrostatic Discharge (ESD)), placement and routing, parasitic extraction and reduction (parasitic devices), Standard Delay Format (SDF) timing data generated by EDA tools, various checks including but not limited to: static timing analysis, cross-talk analysis, IR drop analysis, and electron migration analysis.

At the first step in the ASIC design flow, the design entry step, the circuit is described, as in a design specification of what the circuit is to accomplish, including functionality goals, performance constraints such as power and speed, technology constraints like physical dimensions, and fabrication technology and design techniques specific to a given IC foundry. Further in the design entry step is a behavioral description that describes at a high-level the intended functional behavior of the circuit (such as to add two numbers for an adder), without reference to hardware. Next is a RTL (Register Transfer Language) structural description which references hardware, albeit at a high-level of abstraction using registers. RTL focuses on the flow of signals between registers, with all registers updated in a synchronous circuit at the same time in a given clock cycle, which further necessitates in the design flow that the clocks be synchronized and the circuits achieve timing constraints and timing closure. RTL description captures the change in design at each clock cycle. All the registers are updated at the same time in a clock cycle for a synchronous circuit. A synchronous circuit consists of two kinds of elements: registers and combinational logic. Registers have a clock, input data, output data and an enable signal port. Every clock cycle the input data is stored internally and the output data is updated to match the internal data. Registers, often implemented as flip-flops, synchronize the circuit's operation to the edges of the circuit clock signal, and have memory. Combinational logic performs all the logical functions in the circuit and it typically consists of logic gates. RTL is expressed usually in a Verilog or VHDL Hardware Description Language (HDL), which are industry standard language descriptions. A hardware description language (HDL) is a language used to describe a digital system, for example, a network switch, a memory or a flip-flop. By using a HDL one can describe any digital hardware.

A design flow progresses from logical design steps to more physical design steps. Throughout this flow timing is of critical importance and must be constantly reassessed so that timing closure is realized throughout the circuit, since timing between circuits could change at different stages of the flow. Furthermore, the circuit must be designed to be tested for faults. The insertion of test circuitry can be done at the logic synthesis step, where register transfer level (RTL), is turned into a design implementation in terms of logic gates such as a NAND gate. Thus logic synthesis is the process of generating a structural view from the RTL design output using an optimal number of primitive gate level components (NOT, NAND, NOR, and the like) that are not tied to a particular device technology (such as 32 nm features), nor do with any information on the components' propagation delay or size. In logical synthesis the circuit can be manipulated with Boolean algebra. Logical synthesis may be divided into two-level synthesis and multilevel synthesis. Because of the large number of fan-ins for the gates (the number of inputs to a gate), two-level synthesis employs special ASIC structures known as Programmable-Logic Arrays (PLA) and modified Programmable Array Logic (PAL)-based CPLD devices. Multilevel synthesis is more efficient and flexible, as it eliminates the stringent requirements for the number of gates and fan-ins in a design, and is preferred. The multilevel synthesis implementation is realized by optimizing area and delay in a circuit. However, optimizing multilevel synthesis logic is more difficult than optimizing two-level synthesis logic, and often employs heuristic techniques.

Functional synthesis is performed at the design entry stage to check that a design implements the specified architecture. Once Functional Verification is completed, the RTL is converted into an optimized gate level netlist, using smaller building blocks, in a step called Logic Synthesis or RTL synthesis. In EDA this task is performed by third party tools. The synthesis tool takes an RTL hardware description and a standard cell library for a particular manufacturer as input and produces a gate-level netlist as output. The standard cell library is the basic building block repository for today's IC design. Constraints for timing, area, speed, testability, and power are considered. Synthesis tools attempt to meet constraints by calculating the engineering cost of various implementations. The tool then attempts to generate the best gate level implementation for a given set of constraints, target the particular manufacturing process under consideration. The resulting gate-level netlist is a completely structural description with only standard cells at the “leaves” of the design. At logical/RTL synthesis it is also verified whether the Gate Level Conversion has been correctly performed by performing simulation. The netlist is typically modified to ensure any large net in the netlist has cells of proper drive strength (fan out), which indicates how many devices a gate can drive. A driving gate can be any cell in the standard cell library. During compilation of the netlist the EDA tool many adjust the size of the gate driving each net in the netlist so that area and power is not wasted in the circuit by having too large of a drive strength. Buffer cells are inserted when a large net is broken info smaller sections by the EDA tool.

Throughout the logical design state, an EDA tool performs a computer simulation of the layout before actual physical design.

The next step in the ASIC flow is the physical implementation of the gate level netlist, or physical design, such as system partitioning, floorplanning, placement and routing. The gate level netlist is converted into a geometric representation of the layout of the design. The layout is designed according to the design rules specified in the library for the fab that is to build the digital device. The design rules are guidelines based on the limitations of the fabrication process.

The physical implementation step consists of several sub steps: system partitioning, floorplanning, placement and routing. These steps relating to how the digital device is to be represented by the functional blocks, as one ASIC or several (system partitioning), how the functional blocks are to be laid out on one ASIC (floorplanning) and how the logic cells can be placed within the functional blocks (placement) and how these logic cells are to be interconnected with wiring (routing). The file produced at the output of this physical implementation is the so-called GDSII file, which is the file used by the foundry to fabricate the ASIC.

Floorplanning involves inputting into a floorplanning tool a netlist that describes the interconnection of ASIC blocks (RAM, ROM, ALU, cache controller, and the like); the logic cells (NAND, NOR, D flip-flop, and so on) within the blocks; and the logic cell connectors (e.g., terminals, pins, or ports). Floorplanning maps the logical description as found in the netlist to the physical description, the floorplan.

The goals of floorplanning are to arrange the ASIC blocks on the silicon chip, to decide the location of the I/O pads, to decide the location and number of the power pads, the type of power distribution, and the location and type of clock distribution. Design constraints in floorplanning include minimizing the silicon chip area and minimizing timing delay. Delay is often estimated from the total length of the interconnect and from an estimate of the total capacitance. Interconnect length and predicted interconnect capacitance is estimated from statistics of previously routed chips, including such factors as net fanout and block size of the circuits in the ASIC.

For any design to work at a specific speed, timing analysis has to be performed throughout the ASIC design flow. One must check using a Static Timing Tool in EDA whether the design is meeting the speed requirements of the specification. Industry standard Static Timing tools include Primetime (Synopsys), which verifies the timing performance of a design by checking the design for all possible timing violations caused by the physical design process.

During placement, for example, timing is effected since the length of an interconnect caused by placement changes the capacitance of the interconnect and hence changes the delay in the interconnect. The goal of an EDA placement tool is to arrange all the logic cells within the flexible blocks on a chip to achieve objectives such as: guarantee the router can complete the routing step, minimize all the critical net delays, make the chip as dense as possible, minimize power dissipation, and minimize cross talk between signals. Modern EDA placement tools use even more specific and achievable criteria than the above. The most commonly used placement objectives are one or more of the following: minimize the total estimated interconnect length, meet the timing requirements for critical nets, and minimize the interconnect congestion.

Algorithms for placement do exist, for example, the minimum rectilinear Steiner tree (MRST) is the shortest interconnect using a rectangular grid. The determination of the MRST is in general a NP-complete problem—which is difficult to solve in a reasonable time. For small numbers of terminals heuristic algorithms exist, but they are expensive in engineering cost to compute. Several approximations to the MRST exist and are used by EDA tools.

In the routing step, the wiring between the elements is planned. A Structured ASIC cross-section has metal layers; in a standard cell ASIC there may be nine metal layers, but in many structured ASICs not all metal layers need be for routing, and some layers may be pre-routed, and only the top layers are used for routing. This reduces the complexity of the manufacturing process, since non-recurring engineering costs are much lower, as photolithographic masks are required only for the fewer metal layers not for every layer, and production cycles are much shorter, as metallization is a comparatively quick process. The metal layers may be interconnected with one another at select vertical holes called vias that are filled with metal or some conductor, called the ‘via’ layer, and thus be configurable at this interconnecting layer, or ‘via configurable’. If the logic fabric comprising the Structured ASIC is configured with traditional IC optical lithography involving photolithographic masks, it can be thought of as “mask programmable”. The mask for a Structured ASIC is programmed at the vias, which can be termed a via-configurable logic block (VCLB) architecture. The VCLB configuration and programmability may be performed by changing properties of so called “configurable vias”—connections between VCLB internal nodes. A configurable or programmable via may be in one of two possible states: it may be either enabled or disabled. If a programmable via is enabled, then it can conduct a signal (i.e., the via exists and has low resistance). If a via is disabled, then it cannot practically conduct a signal, i.e., the via has very high resistance or does not physically exist. In some designs, such as by the present assignee to this invention, eASIC Corporation, the customizable metallization layers may be reduced to a few or even a single via layer where the customization is performed, see by way of example and not limitation U.S. Pat. No. 6,953,956, issued to eASIC Corporation on Oct. 11, 2005; U.S. Pat. No. 6,476,493, issued to eASIC Corporation on Nov. 5, 2002; and U.S. Pat. No. 6,331,733, issued to eASIC Corporation on Dec. 18, 2001; all incorporated herein by reference in their entirety. Further, this single via layer could be customized without resorting to mask-based optical lithography, but with a maskless e-beam process, as taught by the '956 patent.

During circuit extraction and post layout simulation, a back-annotated netlist is used with timing information to see if the physical design has achieved the objectives of speed, power and the like specified for the design. If not, the entire ASIC design flow process is repeated. In modern EDA tools the delays calculated from a simulation library of library cells used in the design, during physical design steps, are placed in a special file called the SDF (Synopsys Delay Format) file. Each cell can have its own delay based on where in the netlist it is found, what are its neighboring cells, the load on the cell, the fan-in, and the like. Each internal path in a cell can have a different propagation time for a signal, known as a timing arc. The maximum possible clock rate is determined by the slowest logic path in the circuit, called the critical path.

Compounding the problem of delay is that in a synchronous ASIC one must avoid clock skew, and different parts of the ASIC may have different clock domains controlling them, with the wiring nets that establish the clock signal forming a clock net branching out in the form of a clock tree. Establishing this tree, which often requires additional circuitry like buffer cells to help drive the massive clock tree, is called clock tree synthesis. As an ASIC is a synchronous circuit, all the clocks in the clock tree must be in synch and chip timing control achieved, typically by using Phase-Locked Loops (PLLs) and/or Delay-Locked Loops (DLLs). If the clock signal arrives at different components at different times, there is clock skew. Clock skew can be caused by many different things, such as wire-interconnect length, temperature variations and differences in input capacitance on the clock inputs of devices using the clock. Further, timing must satisfy register setup and hold time requirements. Both data propagation delay and clock skew play important parts in these calculations. Problems of clock skew can be solved by reducing short data paths, adding delay in a data path, clock reversing and the like. Thus during the physical synthesis steps, clock synthesis is an important step, which distributes the clock network throughout the ASIC and minimizes the clock skew and delay.

Finally, IP in the form of proprietary third party functionality such as a semiconductor processor may be embedded in an ASIC using soft macros, firm macros and hard macros that can be bought from third parties. A soft macro describes the IP as RTL code and does not have timing closure given the design specification nor layout optimization for the process under consideration. However, as RTL code a soft macro can be modified by a designer with EDA tools and synthesized into the designer's library. By contrast, a hard macro is timing-guaranteed and layout-optimized for a particular design specification and process technology but is not portable outside the particular design and process under consideration, and is not represented in RTL code; rather a hard macro is tailored for a particular foundry and closer to GDSII layout. A firm macro falls between a hard macro and a soft macro. Firm macros are in netlist format, are optimized for performance/area/power using a specific fabrication technology, are more flexible and portable than hard macros, and more predictive of performance and area to be used than soft macros. Macros obviate a designer having to design every component from scratch, and are a great time saver. Third party designers favor firm and hard macros since it is easier to hide intellectual property (IP) present in such macros than it is to hide such IP in a soft macro.

Given the above, the pros and cons of standard cell ASICs versus a complex field programmable device such as an FPGA is as follows. The advantages of FPGAs are that they are easy to design, have shorter development times and thus are faster in time-to-market, and have lower NRE costs. These are also the disadvantages of standard cell ASICs: they are difficult to design, have long development times, and high NRE costs. The disadvantages of FPGAs are that design size is limited to relatively small production designs, design complexity is limited, performance is limited, power consumption is high, and there is a high cost per unit. These FPGA disadvantages are standard-cell advantages, as standard cells support large and complex designs, have high performance, low power consumption and low per-unit cost at a high volume.

A Structured ASIC falls between an FPGA and a Standard Cell-based ASIC in classification and performance. Structured ASICs are used for mid-volume level designs. In a Structured ASIC the task for the designer is to map the circuit into a fixed arrangement of known cells.

Structured ASICs are closer to standard-cells in their advantages over FPGAs. The disadvantage of structured ASICs compared to FPGAs is that FPGAs do not require any user design information during manufacturing. Therefore, FPGA parts can be manufactured in larger volumes and can exist in larger inventories. This allows the latency of getting parts to customers in the right volumes to be reduced. FPGAs can also be modified after their initial configuration, which means that design bugs can be removed without requiring a fabrication cycle. Design improvements can be made in the field, and even done remotely, which removes the requirement of a technician to physically interact with the system.

Given these pros and cons, structured ASICs combine the best features of FPGAs and standard cell ASICS. Structured ASICs can have three main architectures: fine-grained, where the structured elements are unconnected discrete components, including transistors, resistors and other components; medium-grained, where the structured elements contain generic logic, such as gates, MUXs, LUTs or flip-flops; and, finally, hierarchical design, which contains mini-structured elements such as gates, MUXs and LUTs but no flip-flops for storage, with the flip-flops or registers added later. Hierarchical design has blocks and sub-blocks in a hierarchy, and takes more run time in an EDA tool than a flat design to build. The architectural comparison between fine-grained, medium-grained and hierarchical structured ASICs is that fine-grained structured ASICs require many connections in and out of a structured element, while the higher granularities reduce connections to the structured element but decreases the functionality they can support. Each individual design will benefit differently at these various granularities.

Structured ASIC advantages over standard cell ASICs and FPGAs include that they are largely prefabricated, with components are that are almost connected in a variety of predefined configurations and ready to be customized into any one of these configurations. Only a few metal layers are needed for fabrication of a Structured ASIC, which dramatically reduces the turnaround time. Structured ASICs are easier and faster to design than standard cell ASICs. Multiple global and local clocks are prefabricated in a Structured ASIC. Consequently, there are no skew problems that need to be addressed by the ASIC designer. Thus signal integrity and timing issues are inherently addressed, making design of a circuit simpler and faster. Capacity, performance, and power consumption in a Structured ASIC is closer to that of a standard cell ASIC. Further, structured ASICs have faster design time, reduced NRE costs, and quicker turnaround than standard cell ASICs. Thus with structured ASICs the per-unit cost is reasonable for several hundreds to 100 k unit production runs.

A technology comparison between standard cell ASICs, structured ASICs, and FPGAs, respectively, is roughly as follows: generally speaking, there is a ratio of 100:33:1 between the number of gates in a given area for standard cell ASICs, structured ASICs, and FPGAs, respectively; a ratio of 100:75:15 for performance (based on clock frequency); and a ratio of 1:3:12 for power, though these ratios change year by year and at different process lithographic nodes.

Compared to a field-programmable gate array (FPGA), the unit price of a Structured ASIC solution may be reduced by a significant amount due to the removal of the storage and logic required for configuration storage and implementation. The unit cost of a Structured ASIC may be somewhat higher than a full custom ASIC, primarily due to the imperfect fit between design requirements and a standardized base layer, with certain I/O, memory and logic capacities.

Structured ASIC products may be differentiated by the point at which the user customization occurs and how that customization is actually implemented. Most structured ASICs may only standardize transistors and the lowest levels of metal. A large set of metal and via masks may be needed in order to customize a product. This yields a marginal cost reduction for NRE. Manufacturing latency and yield benefits may also be compromised using this approach.

An ideal ASIC device may combine the field programmability of FPGAs with the power and size efficiency of ASICs or structured ASICs.

A system-on-chip (SoC) is an integrated circuit that implements many or all of the functions of a complete electronic system. The components of a SoC vary with the application. Some SoCs contain mixed signal and analog input/output (IO), but usually most of a SoC is digital. The SoC may contain memory, CPUs (central processing units)/microprocessors, busses, specialized logic and other digital functions. The architecture of the SoC is tailored to an application rather than being general-purpose.

A FET (Field Effect Transistor) is a transistor that uses an electric field to control the conductivity of a charge carrier channel in a semiconductor. A common type of FET is the Metal Oxide Semiconductor FET (MOSFET). MOSFET work by inducing a conducting channel between two contacts called the source and the drain by applying a voltage on the oxide-insulated gate electrode. Two types of MOSFET are called nMOSFET (commonly known as nMOS or NFET) and pMOSFET (commonly known as pMOS or PFET) depending on the type of carriers flowing through the channel. A nMOS transistor is made up of n-type source and drain and a p-type substrate. The three modes of operation in a nMOS are called the cut-off, triode and saturation. nMOS logic is easy to design and manufacture, but devices made of nMOS logic gates dissipate static power when the circuit is idling, since DC current flows through the logic gate when the output is low. By contrast, a pMOS transistor is made up of p-type source and drain and a n-type substrate. PMOS technology is low cost and has a good noise immunity. In a nMOS, carriers are electrons, while in a pMOS, carriers are holes; since electrons travel faster than holes, all things being equal NFETs are twice as fast as PFETs. When a high voltage is applied to the gate, with the gate-source voltage exceeding some threshold value (V_{Gs}>V_{TH}), the nMOS will conduct, while pMOS will not; and conversely when a low voltage is applied in the gate, nMOS will not conduct and pMOS will conduct. PFETs are normally closed switches and NFETs are normally open switches. PFETs often occupy more silicon area than NFETs when forming logic blocks. PMOS devices are more immune to noise than nMOS devices. Furthermore, nMOS ICs are smaller than pMOS ICs with the same functionality, since the nMOS can provide one-half of the impedance provided by a pMOS under the same geometry and operating conditions.

Complementary metal-oxide-semiconductor (CMOS) is a technology for constructing integrated circuits. CMOS is sometimes referred to as complementary-symmetry metal-oxide-semiconductor (or COS-MOS). The words “complementary-symmetry” refer to the fact that the typical digital design style with CMOS uses complementary and symmetrical pairs of p-type and n-type metal oxide semiconductor field effect transistors (MOSFETs) for logic functions. Complementary Metal-Oxide-Silicon circuits require an nMOS and pMOS transistor technology on the same substrate. An n-type well is provided in the p-type substrate. Alternatively one can use a p-well or both an n-type and p-type well in a low-doped substrate. The gate oxide, poly-silicon gate and source-drain contact metal are typically shared between the pMOS and nMOS technology, while the source-drain implants are done separately. Since CMOS circuits contain pMOS devices, which are affected by the lower hole mobility, CMOS circuits are not faster than their all-nMOS counter parts. Even when scaling the size of the pMOS devices so that they provide the same current, the larger pMOS device has a higher capacitance.

The CMOS advantage is that the output of a CMOS inverter can be as high as the power supply voltage and as low as ground. This large voltage swing and the steep transition between logic levels yield large operation margins and therefore also a high circuit yield. In addition, there is no power dissipation in either logic state. Instead the power dissipation occurs only when a transition is made between logic states. CMOS circuits are therefore not faster than nMOS circuits but are more suited for very/ultra large-scale integration (VLSI/ULSI).

In electronics, a multiplexer (MUX or mux), sometimes called a data selector, is a circuit that selects one of several analog or digital input signals and forwards the selected input into a single line. A multiplexer of 2n inputs has n select lines, which are used to select which input line to send to the output. Demultiplexers take one data input and a number of selection inputs, and they have several outputs. Similarly, a decoder is a circuit that performs the reverse operations of an encoder.

In integrated circuits often clock signals need to be adjusted for skew and for timing, with the adjustment occurring as a fraction of a normal clock cycle period. This can be done through Digitally Controlled Delay Line (DCDL) circuitry, such as found in the prior art, see U.S. Pat. No. 5,465,076, to Yamauchi et al., issued Nov. 7, 1995, incorporated by reference herein. DCDLs are also used with Delay Locked Loops (DLLs).

The trouble with some of the prior art is that the minimum delay may be too large, the range may be too small or not scalable, glitches of the clock signal may result from the architecture employed for the DCDL and resolution may not be fine enough. Minimum delay occurs from a DCDL circuit design architecture if a clock signal has to pass through a number of delays before it can be output again, with each of these delays summing together to produce a minimum delay that may be unacceptably large for a design. Range is a function of how many stages can be safely added to a design to still achieve a scalable, useable output, and depends on the architecture. Clock glitches should always be avoided but are sometimes unavoidable in certain DCDL architectures that are otherwise acceptable. Regarding resolution, certain architectures will only achieve a “coarse” tuning of the clock signal, meaning the unit of time by which the clock signal may be delayed is relatively large, as opposed to a “fine” tuning, which achieves a comparatively smaller delay. Coarse tuning is due to employing an entire gate to slow down a clock signal, as opposed to fine tuning where sub-gates are used. However, coarse tuning is sometimes useful to give a designer a range of clock delays, and should optimally be available in addition to fine tuning.

FIG. 1 (Prior Art) shows an example of a “fine tuning′” DCDL delay unit 10, comprising a CMOS configuration having plurality of pMOS transistors and nMOS transistors in parallel that surround an inverter 32 having an input IN and an output OUT through which a clock signal is delayed. The DCDL 10 comprises, in the pMOS transistors, a first transistor, 13, having a gate 12, a second transistor T′01, 15, in parallel with the first transistor 13, the second transistor T′01 having a gate 14, and a last transistor, T′21, 17, having a gate 16, in parallel with the other pMOS transistors, which all except the first transistor have their gates connected to output lines from a 2-bit Binary-to-Thermometer Decoder 20, that controls their gate voltages through a plurality of voltage thresholds output as a control signal by the Binary-to-Thermometer Decoder 20. A source Vss comprising a negative supply voltage or ground is connected to the gate 12 of the first transistor 13 while the remaining gates are connected to predetermined outputs 21 from the 2-bit Binary-to-Thermometer Decoder 20, the outputs 21 forming control signals.

The 2-bit Binary-to-Thermometer Decoder 20 supplies a plurality of different voltages T, output in response to a two-bit binary code signal input as thermometer values (unary coding), meaning for example a binary 0 is output as 000, a binary 1 is output as 001, a binary 2 is output as 011, a binary 3 is output as 111, a binary 4 is output as 1111, a binary 5 is output as 11111, a binary 6 is output as 111111, a binary 7 is output as 1111111, a binary 8 is 11111111, a binary 9 is 111111111, a binary 10 is 1111111111. The incorporation of zero is also possible in such a unary coding scheme, as are alternative schemes where the compliment of the output is taken.

The 2-bit Binary-to-Thermometer Decoder 20 will convert a 2-bit binary number input into an equivalent thermometer value output, which can represent voltage values. When a predetermined thermometer voltage value output is received by the gates 12, 14, and 16 of pMOS transistors 13, 15, and 17, and the gate-source voltage of the P-type MOSFETs exceeds the threshold value, certain of the pMOS transistors will conduct, depending on the value received. This increases the flow of the current into the source of the PFET transistor 22, which forms part of the inverter 32. Increasing the thermometer values output from decoder block 20 from a low number to higher number will cause more of the pMOS transistors at the top of the circuit to conduct.

Likewise, a similar thing happens when thermometer voltage values are input into the nMOS transistors 24, 26 and 28, connected in parallel as shown. The first nMOS transistor 24 is connected at its gate to Vdd, the positive supply voltage, and certain transistors, such as nMOS transistors 26, 28, depending on the thermometer voltage value from Decoder block 20 input into their gates, will conduct when their gate-source voltage exceeds a threshold value, which will increase the flow of current into the source of the NFET transistor 30, which forms part of the inverter 32. The net effect of increasing the thermometer values is that more current will flow into the sources of the PFET transistor 22 and the NFET transistor 30, which will increase the current flow through inverter 32. An analysis of the fine-tuning DCDL circuit 10 of FIG. 1 shows, due to the RC and other effects from this increased current flow, that increasing the thermometer values output by the Decoder block 20, and turning on the CMOS transistor gates 15, 17, 26, 28 to conduct will result in a decrease of the delay to a signal as it passes from input IN to output OUT in the inverter configuration shown in FIG. 1 (Prior Art). Likewise, not turning on these CMOS transistors gates to conduct will result in a larger delay by inverter 32 than otherwise as a signal passes from IN to OUT. In addition, not turning on certain CMOS transistor gates will result in an intermediate predetermined delay between turning all the CMOS transistor gates on and turning all the CMOS transistor gates off. Consequently the circuit of FIG. 1 (Prior Art) acts as a variable delay, fine-tuning DCDL circuit, but not as a coarse-tuning DCDL circuit.

What is lacking in the prior art is a DCDL circuit for use in a Structured ASIC that combines fine-tuning and coarse-tuning in a single circuit, has a small minimum delay, a large range that is scalable, provides a fine resolution when used in fine-tuning mode and whose output is glitch free. What is further needed is a DCDL tied to a via-configurable, balanced and scalable high-speed routing fabric of novel configuration. The present invention has these features.

### SUMMARY OF THE INVENTION

Accordingly, an aspect of the present invention is to provide a Digitally Controlled Delay Line (DCDL) for a Structured ASIC, manufactured using a CMOS process using NFET/nMOS and PFET/pMOS transistors, which may include together with the DCDL a via-configurable logic block (VCLB) architecture. VCLB configuration may be performed by changing properties of so-called “configurable vias”—connections between VCLB internal nodes and elements in a Structured ASIC.

An aspect of the present invention is to provide a DCDL circuit that combines fine-tuning and coarse-tuning in a single circuit.

An aspect of the present invention is to provide a DCDL that has a small minimum resolution for delay.

As aspect of the present invention is to provide a DCDL that has a small minimum delay.

A further aspect of the present invention is for a DCDL that is scalable and has a large range, from minimum delay to maximum delay.

Another aspect of the present invention is to provide for a DCDL which produces glitch free output over its entire range.

Yet another aspect of the present invention is to tie the DCDL to a high-speed routing fabric that is automatically balanced, inherently supports a tree, and is scalable.

The sum total of all of the above advantages, as well as the numerous other advantages disclosed and inherent from the invention described herein, creates an improvement over prior techniques.

The above described and many other features and attendant advantages of the present invention will become apparent from a consideration of the following detailed description when considered in conjunction with the accompanying drawings.

### BRIEF DESCRIPTION OF THE DRAWINGS

Detailed description of preferred embodiments of the invention will be made with reference to the accompanying drawings. Disclosed herein is a detailed description of the best presently known mode of carrying out the invention. This description is not to be taken in a limiting sense, but is made merely for the purpose of illustrating the general principles of the invention. The section titles and overall organization of the present detailed description are for the purpose of convenience only and are not intended to limit the present invention.

In an actual chip layout the exact placement of the blocks shown therein may vary from the simple stylized representations as shown in the drawings, and in addition there may be several layers in an ASIC chip that achieve the functionality shown in the figures, superimposed on one another, and not necessarily a single layer as shown in the drawings. This is true for most of the elements in the present invention, as understood by one of ordinary skill, and that does not detract from any of the teachings of the functional relationships between the elements of the present invention as shown herein. Furthermore, designations of orientations such as north-south or east-west are relative to the observer and depend on the chip as outlined in the drawings; hence these orientations are for convenience only and do not limit the invention, other than indicating that the north-south direction is orthogonal to the east-west direction, in the same way that a vertical direction is orthogonal to a horizontal direction.

FIG. 1 (Prior Art) is prior art of a fine-tune Digitally Controlled Delay Line (DCDL) circuit.

FIG. 2A is portion of the Digitally Controlled Delay Line (DCDL) circuit of the present invention showing the fine-tune stage.

FIG. 2B is a portion of the Digitally Controlled Delay Line (DCDL) circuit of the present invention showing the coarse-tune stage.

FIG. 3A is a detailed view of the fine-tune portion circuitry of the DCDL;

FIG. 3B is a detailed view of another embodiment of the fine-tune portion circuitry of the DCDL

FIG. 4 shows a plurality of fine-tune and coarse-tune stages comprising the DCDL.

FIG. 5 is the floor plan for layout of the Delay Tap, comprising fine-tune delay stage, a coarse-tune delay, and decoders for both.

FIGS. 6 and 7 are a schematic of the generalized floor plan layout of Structured ASIC of the present invention in block diagram form.

FIG. 8 shows an IO routing fabric for the Structured ASIC of the present invention.

FIG. 9A shows the network-aware IO fabric in which the DCDL appears in, adjacent to a logic unit block used for the Structured ASIC of the present invention.

FIG. 9B shows a more detailed close up view of a portion of FIG. 9A.

FIG. 10 shows a close up portion of a unit of high-speed routing fabric of the kind employed with the DCDL of the present invention.

FIG. 11 shows the high-speed routing fabric as it is deployed in the Structured ASIC of the present invention for use with the DCDL.

It should be understood that one skilled in the art may, using the teachings of the present invention, vary embodiments shown in the drawings without departing from the spirit of the invention herein. In the figures, elements with like numbered reference numbers in different figures indicate the presence of previously defined identical elements.

### DETAILED DESCRIPTION OF THE INVENTION

The method and apparatus of the present invention may be described in software, such as the representation of the invention in an EDA tool, or realized in hardwire, such as the actual physical instantiation.

Regarding the floorplan of the present invention, the drawings sometimes show elements as blocks that in a physical implementation may differ from this stylized representation, but the essential features of the floorplan should be apparent to one of ordinary skill in the art from the teachings herein.

The elements in the floor plan of the present invention are operatively connected to one another where necessary, as can be appreciated by one of ordinary skill in the art from the teachings herein.

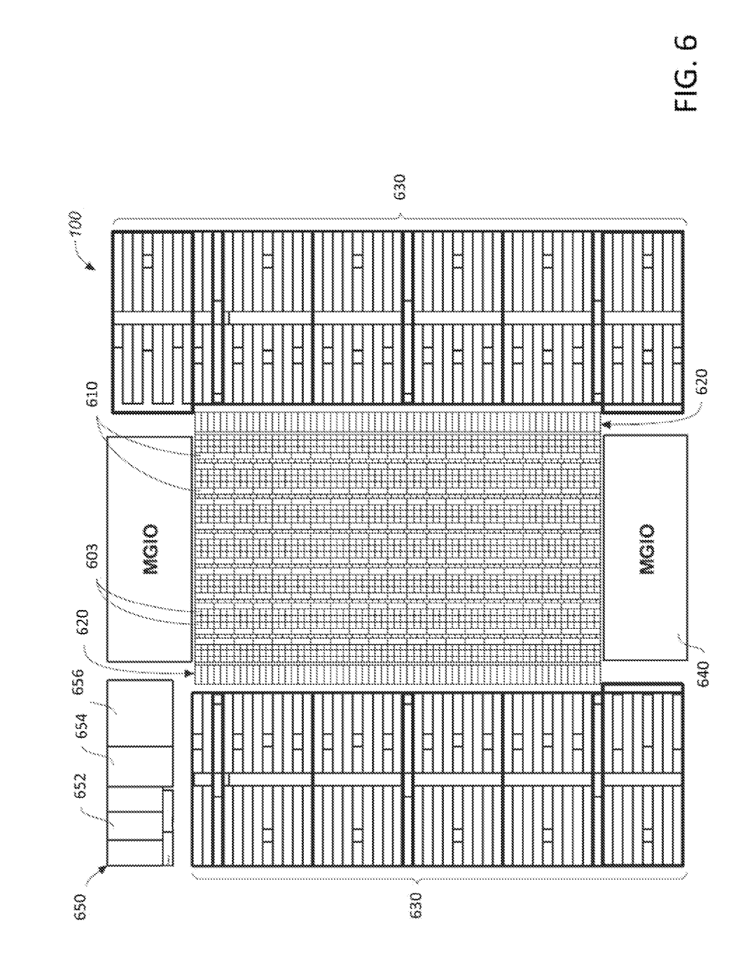

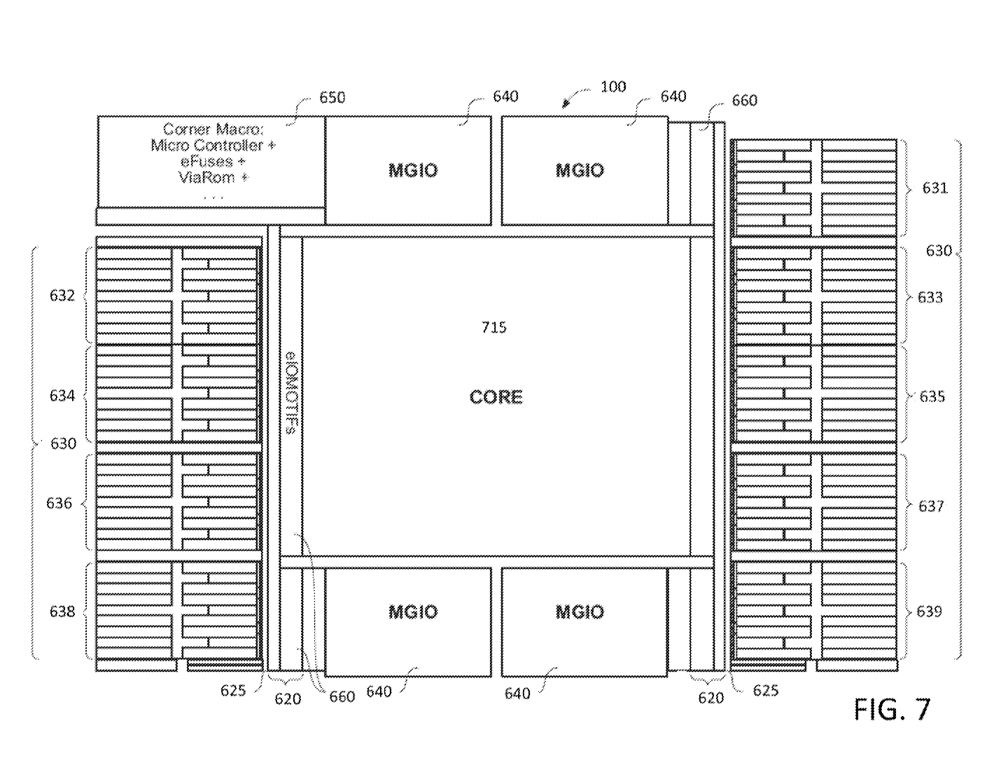

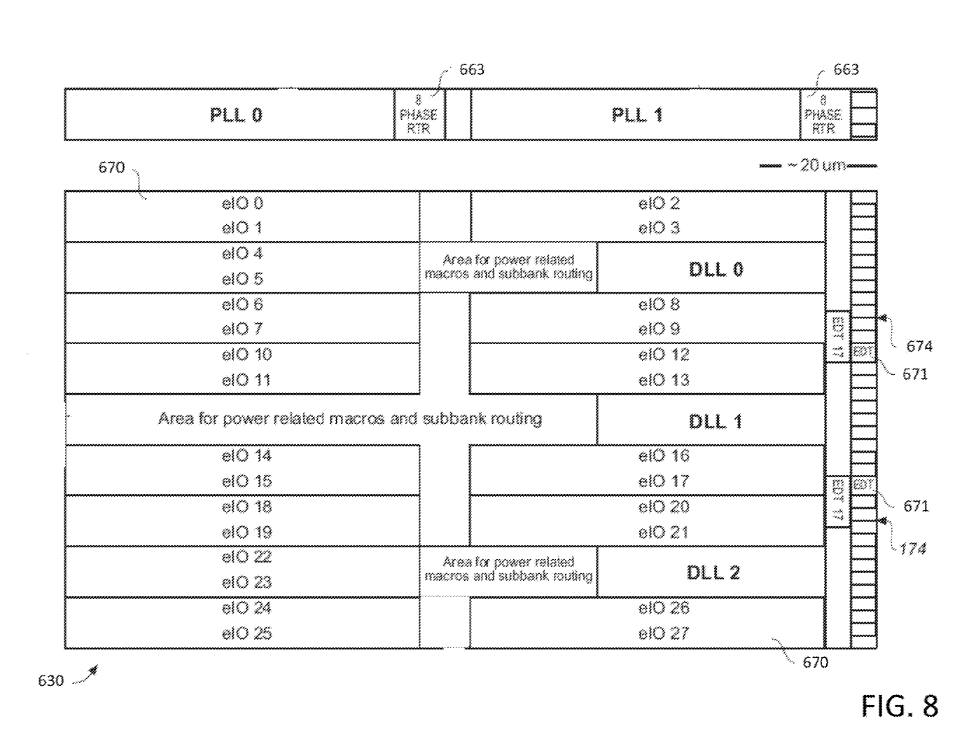

The Digitally Controlled Delay Line (DCDL) of the present invention, in particular as shown in the drawings, is for delaying input or output signals, such as PLL, DLL or clock signals, but may also include delaying IO signals (which sometimes require delay due to various IO standards) and other signals into or out of the core logic 715 of the chip 100, which is shown in the drawings in FIGS. 6 and 7, termed the Ruby architecture. The DCDL also can be used with any Phase Locked Loops (PLLs) or DLL in the peripheral IO regions of the core of the RUBY chip such as IO region 630, as shown in FIG. 8.

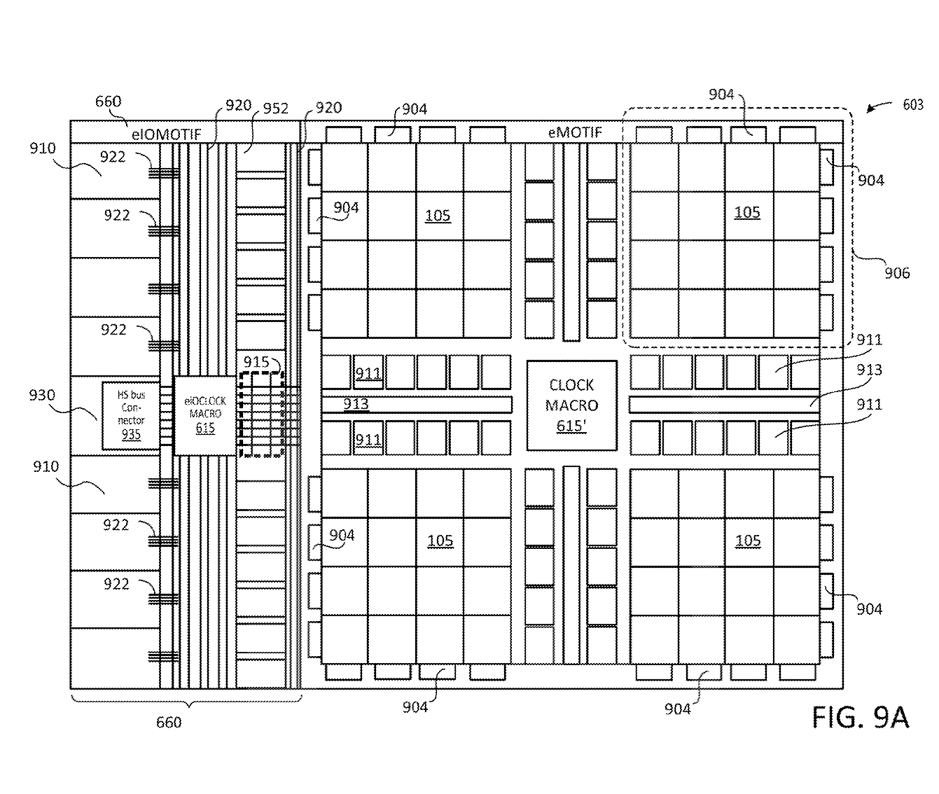

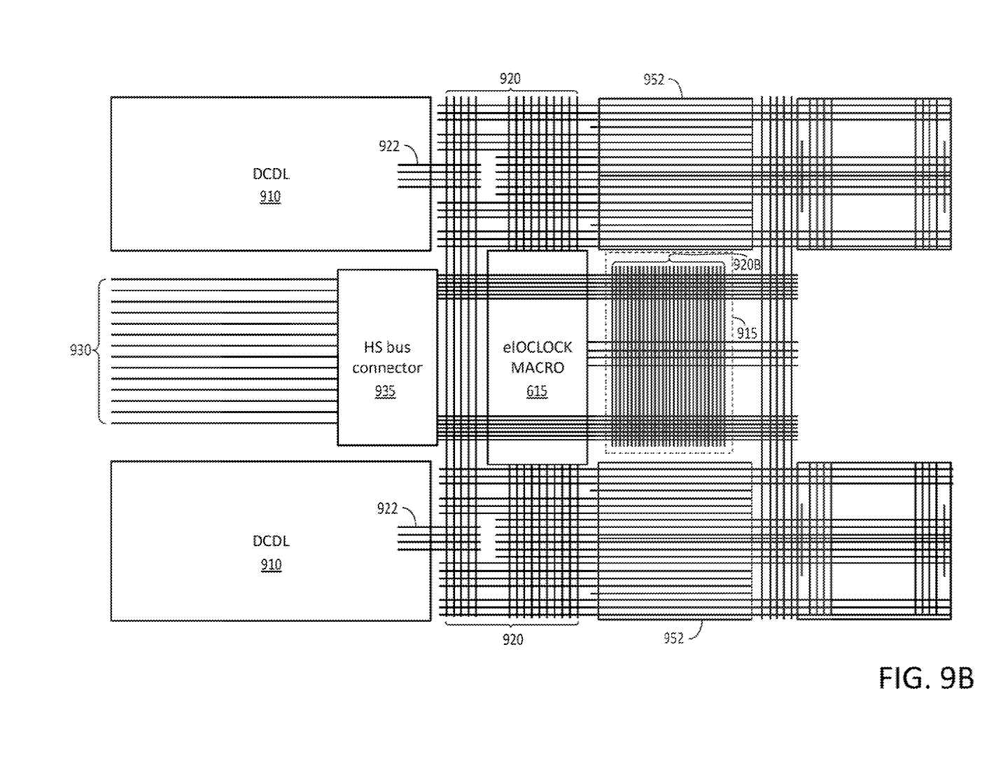

One purpose of the DCDL is to perform a wide range of timing delays that can be controlled and calibrated using digital signals from any control state machines implemented in the core logic. Each delay line may be composed of eight independent Delay Taps, as further described herein and as shown in FIG. 9A, that can be connected in series to achieve the biggest delay, each delay line made into a macro 910 that is to fit in the space 620 between the IO routing fabric 630 and the core 715, and each delay line fits next to a logic block eMotif 603. The delay line blocks may be placed into an IO fabric 660 deemed eIOMOTIF, as shown in FIGS. 6, 7 and 9A, which fits in space 620. The DCDL can be treated as a sub macro of the eIOMOTIF fabric and operatively connected thereto.

The controller for the DCDL is found in the core 715, and has its own control logic. The lines from the DCDL controller in core 715 to the DCDL that is found in the eIOMOTIF portion 660 of the chip are sent in Grey encoded binary code rather than thermometer binary code in order to save space on the chip 100, since Grey code takes fewer signal lines to send and is converted to thermometer code for controlling the DCDL circuit.

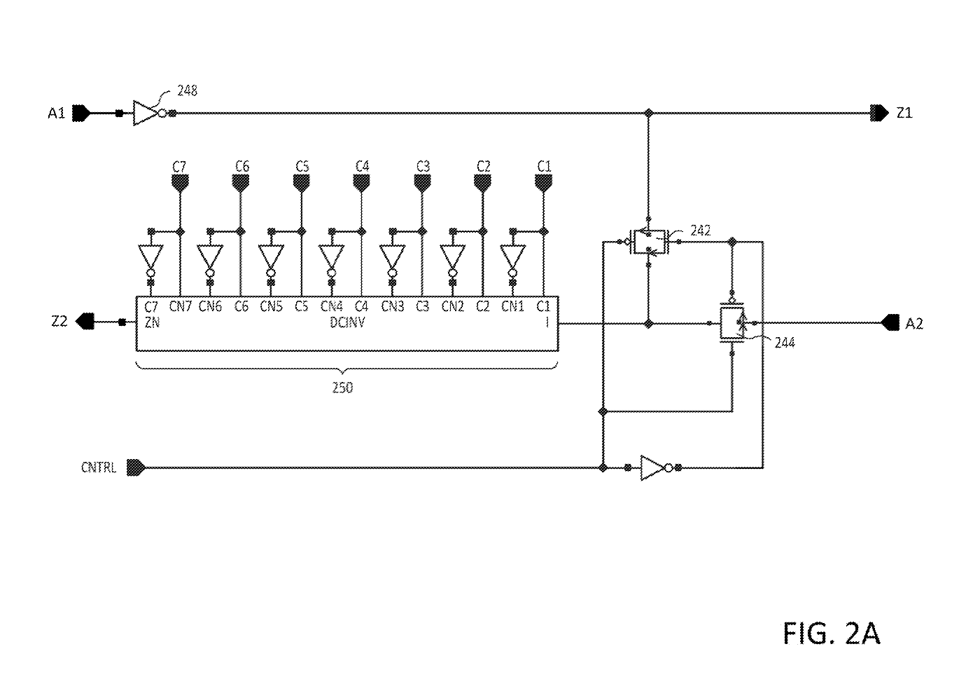

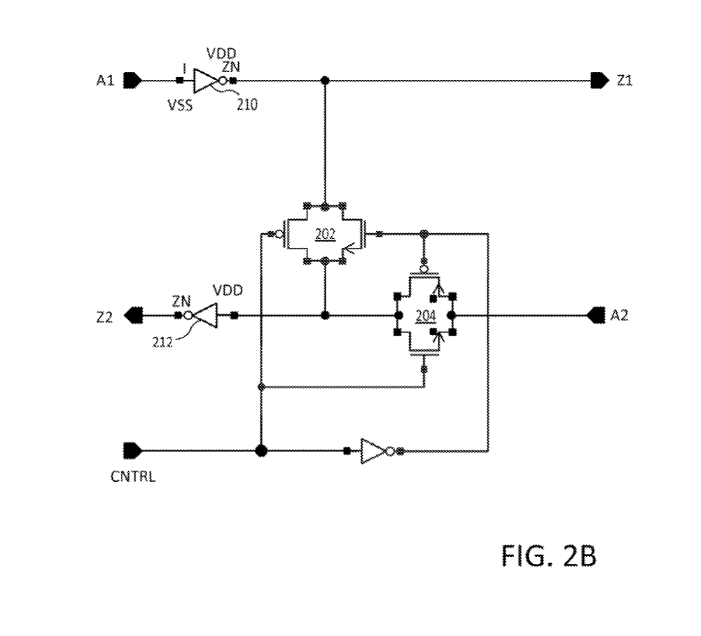

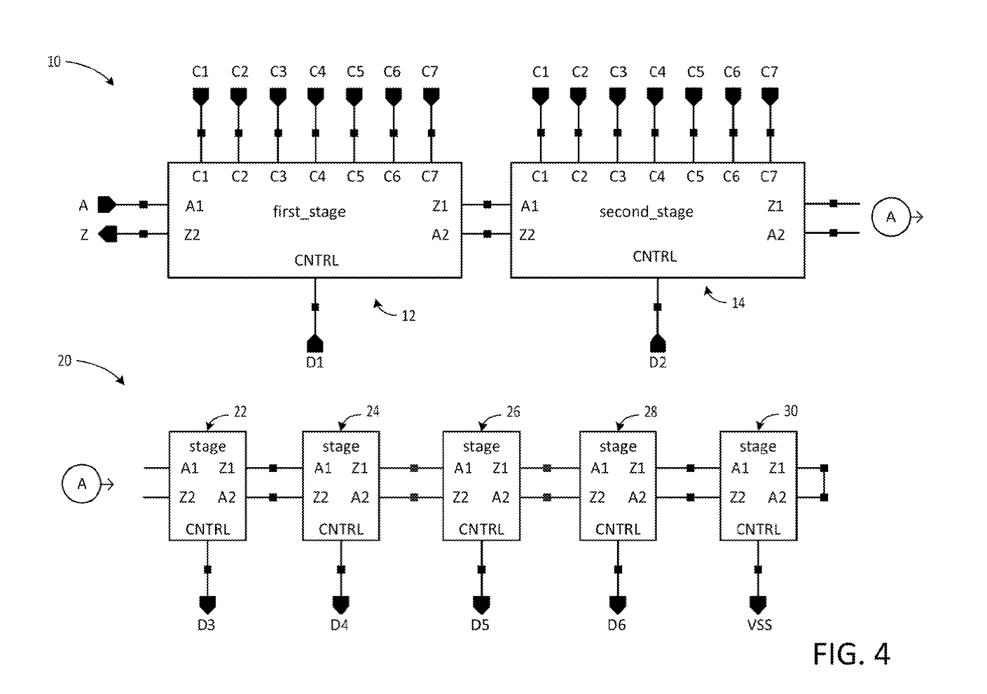

In order to meet the timing requirements, in the present invention the DCDL delay circuit is implemented using a fine controllable delay section, such as shown in FIG. 2A, and a coarse controllable delay section, such as found in FIG. 2B, in the configuration shown in FIG. 4. A multi-stage MUX based lattice is used, such as found in FIG. 4, where the first two stages are implemented for fine grain control, fine delay tuning, followed by multiple stages (e.g. five in FIG. 4) for coarse grain control, coarse grain tuning. All stages have thermometer-based decoding from Gray codes as control signals. The first two stages require seven thermometer steps each, that should be decoded from four Gray coded bits, while the coarse stages require one thermometer step per stage (in N stages), and a corresponding number of Gray coded bits (log2N bits compared to the N bits of the thermometer stage). Each stage of the lattice primarily consists of a pass-gate mux and an inverter, with suitable control circuitry.

Turning attention to FIGS. 2A, 2B and 4, there is shown the Digitally Controlled Delay Line (DCDL) of the present invention that is used to manipulate a signal, typically a clock signal, by delaying it, and generally has two stages, a fine delay, fine-tune stage 10, determined by a series of transistors in a unique configuration (“sub-gate delay”), and a coarse delay, coarse tune stage 20 determined by a plurality of logical gates (“gate-delay”). The fine delay and course delay are combined into a plurality of modules in series as best shown in FIG. 4. These modules can be deemed either fine-delay modules (modules 12, 14 in FIG. 4), or coarse-delay modules (modules 22, 24, 26, 28 and 30 in FIG. 4), with the distinction between fine delay and course delay being that the resolution in time delay of a signal in a fine-delay module is such that the fine-delay module is capable of delaying a signal by a minimum amount of time less than the amount of time that the signal can be delayed by a course-delay module (e.g., 25 ps for the former versus 100 ps for the latter), or, conversely, a coarse-delay module is capable of delaying a signal by a minimum amount of time that is greater in time than the minimum amount of time that a fine-delay module is capable of delaying the signal, hence the designations of ‘coarse’ and ‘fine’, which can also be termed “coarse grain control” and “fine grain control”. In both the fine grain control and coarse grain control inverters the delay is produced by a delay-producing inverter, which is the simplest form of logic gate to manufacture, but in general this term can designate without loss of generality any logic gate that produces delay. In the fine grain control module, the degree of delay that can be produced by the inverter is adjustable, as explained more fully herein.

The DCDL of FIG. 4 has an initial input A for a signal and final output Z for that signal after it is delayed by the DCDL, and there are two fine-delay, fine grain control, fine-tune or sub-gate delay modules, modules 12, 14 in FIG. 4, connected in series, each having an input A1 and an output Z1, the output Z1 connected to a neighboring downstream module with output A1, comprising either another fine-tune module or a coarse-tune module, and the return path comprising an input A2 receiving from an output Z2, with the return path (upstream path) leading to the final output Z of the DCDL 10. As shown these fine-delay (or fine grain control) modules 12, 14 are followed downstream of the signal path by five course delay, coarse tune, or coarse grain control modules 22, 24, 26, 28, 30 having inputs A1 and outputs Z1 for the downstream path and outputs Z2 inputting into inputs A2 for the upstream return path back to final output Z. In general any number of fine-delay or coarse-delay modules may be used, limited only by the number of thermometer signal lines there are present. In the present configuration, based on the fact eight bits are sent by a DCDL controller in Grey code, having 4 bits in separate lines that are decoded into thermometer code as explained herein by a binary-to-thermometer decoder, a total of 2̂4=16 bits may be used to control the fine and coarse stages of the DCDL, and if seven bits are used to control the fine stages, then two fine-stage modules may be employed (7+7<16), and if 1 bit is used to control the coarse stages, then up to 16 coarse stages may be employed (though in FIG. 4 only five coarse stages are shown).

The description of the operation of the five coarse delay modules 22, 24, 26, 28, 30 is that they operate as traditional gate-delay devices comprising muxes, in that when a predetermined control signal is received by the multiplexer, the input signal (typically a clock signal) is either sent to output Z1 or output Z2. Hence in FIG. 2B, a portion of the Digitally Controlled Delay Line (DCDL) circuit of the present invention showing the coarse-tune stage, the CMOS transistor configurations 202, 204 act as a pass-gate mux to allow, if instructed by the control line CNTRL, a signal from input A1, that originated from initial input A that is being passing downstream, to pass through inverter 210 and to continue to output Z1, downstream, and at the same time a signal from input A2 is allowed to pass through inverter 212, upstream, or, if the proper predetermined control signal is input to control line CNTRL, the signal at input A1 is diverted so the signal passes through inverter 212 and to output Z2. On the return of the signal being delayed, to the upstream side back to final output Z, a signal entering into input A2 simply will pass through the pass-gate transistors 204, which may slightly delay the signal, and inverter 212 which further delays the signal, when a predetermined control signal is given at line CNTRL. The control signal CNTRL is a thermometer coding control signal. Thus the pass-gate mux configuration of transistors 202, 204, of the coarse delay module of FIG. 2B, selectively controls and determines the signal path of the input at A1, depending on the thermometer coded control signal received by the mux at control line CNTRL, to either one of the outputs Z1 or Z2, so that either the signal from input A1 will pass through both the inverter 210 and 212 and will be output to Z2 (i.e. a gate-level delay comprising substantially the delays through inverters 210 and 212, as well as some small delay caused by intermediate transistors), or the signal will pass through to Z1 (i.e. a gate-level delay comprising substantially the delay through inverter 210), and be delayed only by inverter 210. A signal received from A2 will pass through to Z2, through the inverter 212 (as well as some small delay caused by pass-gate intermediate transistors) and be delayed by a gate-level delay unit for a certain predetermined time. Hence, in the coarse gain module of FIG. 2B, if the thermometer-coded control signal at CNTRL instructs the pass-gate mux structure to operate to divert the signal from A1 to Z2, through inverter 212, then the signal will not be further delayed by another neighboring coarse gain module by being sent downstream, but will only be delayed by the coarse gain module primarily by inverters 210, 212 (as well as any small delay from intermediate transistors). If, however, the thermometer-coded control signal at CNTRL instructs the pass-gate mux structure to operate to divert the signal from A1 to Z1, the signal will be delayed only by inverter 210 while going downstream to the neighboring module, where the signal may be further delayed by the neighboring module. The signal passing from A1 to Z1 will then travel to the next downstream neighboring coarse delay module after being output at Z1, and the downstream neighboring coarse delay module would then have the option of repeating this process of either diverting the input clock signal to any neighboring module at output Z1 after a delay at its inverter 210, or, sending the clock signal through its inverter output Z2, such as inverter 212. Any return signal to the upstream side will pass through coarse delay module inputs A2 and be delayed primarily by inverter 212, inter alia, and eventually return to final output Z. Thus it can be seen that through this method, depending on what the control signals are to control signal input CNTRL in FIG. 2B for each coarse delay module, a signal will be delayed by each coarse delay module in FIG. 2B by a predetermined gate-delay unit of time, which is comparatively larger in time than any sub-gate delay, as associated with the fine delay module and as discussed further herein.

At some point, depending on how many stages of coarse delay modules there are (five are shown in FIG. 4 but more or fewer may be present), if the input signal is diverted to the last coarse delay module in the chain, the input signal or clock signal must return back to final output Z, and hence for maximum delay from all the coarse grain modules an input signal at initial input A would be diverted by suitable application of a thermometer-coded control signal input to each of the control input CNTRL of coarse gain modules 22, 24, 26, 28, 30 so that the signal will pass to the farthest away coarse grain module, such as module 30, and pass through each of the coarse delay modules for both the upstream and downstream paths. In the course of this signal traversal through the modules a certain predetermined amount of time will elapse as the signal makes its way through the gates in the modules (primarily by the delay associated with inverters 210 and 212). Hence, a series of thermometer coded signals can be input into the five coarse delay modules 22, 24, 26, 28, 30 to divert a signal traveling from initial input to final output Z into either one or more modules, designated by their reference number, such as by way of example the coarse delay module delay paths: A→22→Z; A→22→24→22→Z; A→24→26→24→22→Z; A→22→24→26→28→26→24→22→Z; A→22→26→28→30→28→26→24→22→Z. As a signal passes though the top part of the coarse grain module going downstream from initial input A until it returns through the bottom part of the module going upstream as discussed in FIGS. 2B and 4, a signal will be delayed by each module by a gate-delay unit of time, e.g., time Delta T1 Coarse Grain.

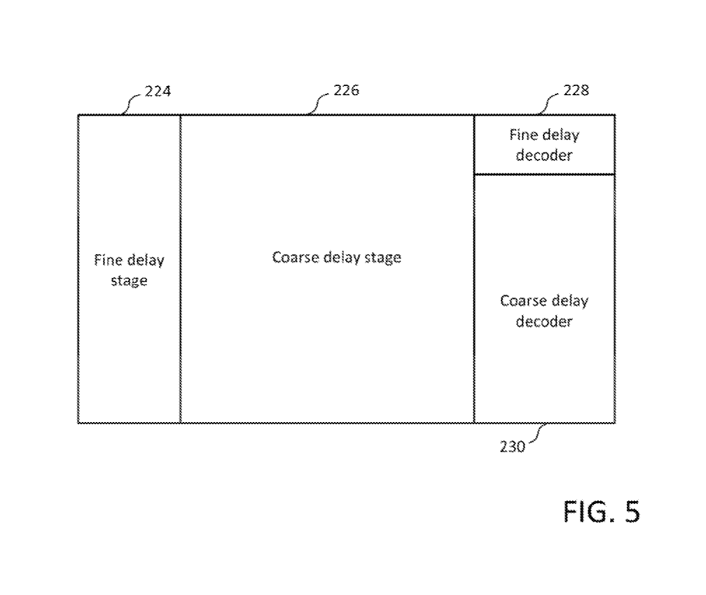

As discussed, the coarse gain modules 22, 24, 26, 28, 30 will respond to five thermometer control signals. The thermometer control signals are output from a coarse delay decoder 230, as shown in FIG. 5, which receives from a DCDL controller, found in the core 715 (not shown) a signal that is output in 4 bit Grey code and is decoded by the coarse delay decoder to produce 15 bits of thermometer code, 1 bit per coarse module. It takes fewer signal lines to send Grey encoded binary signals rather than thermometer binary signals. Hence this arrangement can support up to 15 coarse modules (1 bit per coarse module). Consequently, if it is desired to delay (by a gate-delay amount of fixed time) one of the coarse gain modules, a signal from the coarse delay decoder may be sent to cause the coarse delay module to divert an input signal along such a signal path as to create gate-level delay, e.g. a signal in thermometer code such as 0000 . . . 0001 (ellipses indicating more zeros); while if two coarse gain modules are desired to be activated to delay a signal, the coarse delay decoder can and out a signal 0000 . . . 0011; for three gate-delays from three activated coarse gain modules the signal may be 0000 . . . 0111; and so forth, up to the maximum number of coarse gain modules, with the understanding any number of thermometer encoding schemes may be employed. As can be seen in the FIG. 4 embodiment two of the coarse delay signal lines, D1 and D2, are reserved to control fine delay modules, as will be explained further herein, while the other signal lines D3, D4, D5, D6 control the coarse delay modules.

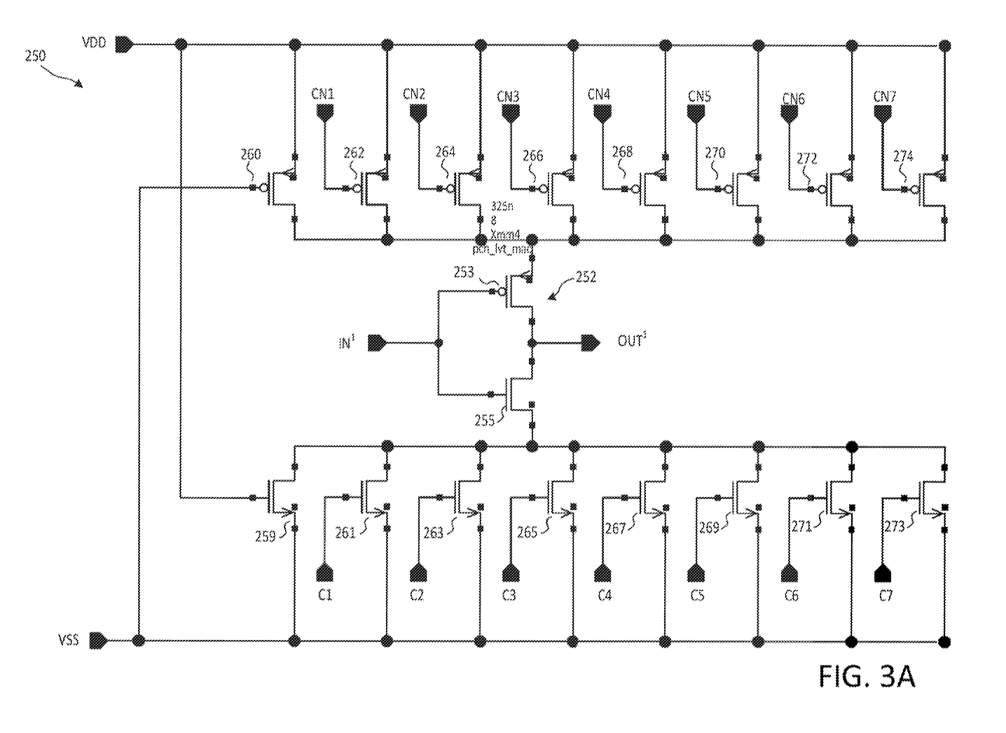

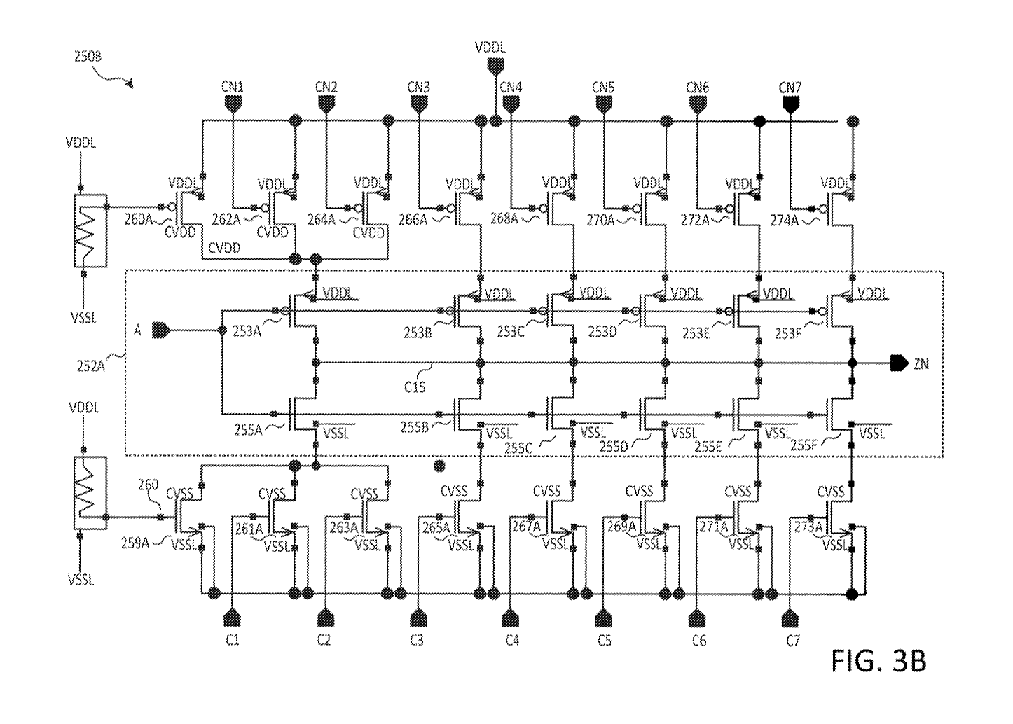

By contrast to the coarse delay modules, the fine-delay modules 12, 14 have the ability to route a signal to be delayed, such as a clock signal, by a more graduated and precise series of unit times, a series of “sub-gate delay” unit times, which are smaller than the coarse grain module “gate-delay” unit of time in their minimum value (minimum resolution), and, when summed together, may be smaller than the coarse grain module gate-delay unit of time. Referring to FIG. 2A and FIG. 3A, basically the fine delay modules are exactly the same as coarse delay modules but instead of a regular inverter they contain a submodule shown in one embodiment in FIG. 3A. Therefore the fine delay modules are controlled by the same single-bit CNTRL input as the coarse delay modules, but in addition to that input they also have a number of control inputs for that submodule as shown on FIG. 3A. Thus, similar to before, and referring to FIG. 2A, a signal at the input A1 is diverted by employing a control signal at input “CNTRL”, which instructs the transistor configurations 242, 244, acting as a pass mux, to either let pass a signal that is to be delayed, to pass from the input line A1 to output Z1, and to pass through inverter 248 to output Z1, in which case the signal is not delayed as much (except for a small delay through inverter 248) but will continue to the next downstream module, or, if the correct input control signal at input line “CNTRL” is given, the signal to be delayed passes from A1 through a sub-gate delay logic array 250, as described in more detail in FIG. 3A, and out through to output Z2. On the return side, an input A2 can receive any signal from a neighboring module, and passes the signal through the sub-gate delay logic array 250. If a signal is passed to output Z1, it can be delayed by other blocks downstream that are connected in series to the block, such as another fine delay module or by a coarse delay module. Likewise, a return signal going upstream to the output and received at input A2 of fine-delay module 12 or 14 as shown in FIG. 2A can pass through the sub-gate delay logic array 250 if the proper control signal is input at line CNTRL. It can be noted that sub-gate delay logic module 250, as shown in FIG. 3A, has as a default delay almost as small as an inverter, but the degree of delay may be varied greater depending on the signals to certain transistors, for example as shown in the embodiment of FIG. 3A, as explained further herein.

The sub-gate delay logic array 250 is a fine-delay, sub-gate delay circuit shown in detail in the embodiments of FIGS. 3A and 3B, and acts to delay the signal by a variable amount. In FIG. 3A, the fine-delay portion of the sub-gate delay logic array comprises an inverter 252, comprised of CMOS transistors consisting of pFET transistor 253 and nFET transistor 255, forming an inverter 252 connected to a plurality of CMOS transistors in parallel at the tops and bottom having gates CNi or Ci (i=1, 2, 3, . . . ).

In FIG. 3A the CMOS transistors in parallel comprise transistors 260, 262, 264, 266, 268, 270, 272, 274 (pMOS) and transistors 259, 261, 263, 265, 267, 269, 272, 273 (nMOS), with the first two transistors 259, 260 from the plurality of CMOS transistors in parallel being connected at their gates to Vdd and Vss, positive and negative (ground) voltage, respectively, and the remaining seven P-type MOSFET transistors 262, 264, 266, 268, 270, 272, 274 that are in parallel to the first transistor 260 and seven N-type MOSFET transistors 261, 263, 265, 267, 269, 272, 273 that are in parallel to the first transistor 259 having their gates connected to fine-stage decoder thermometer decoder outputs CN1, CN2, CN3, CN4, CN5, CN6, CN7 for the PFET transistors and fine-stage decoder thermometer decoder outputs C1, C2. C3, C4, C5, C6, C7 for the NFET transistors. The output (e.g. the drain) of these parallel CMOS transistors are tied to the inverter 252 at the pMOS transistor 253 for the P-type MOSFET transistors, and at nMOS transistor 255 for the N-type MOSFET transistors, as shown, operatively connected to the inverter 252. This fine-delay structure described in this paragraph and in reference to FIG. 3A can be deemed, for ease in description, as a structure comprising a delay-producing inverter bracketed by a pair of parallel CMOS transistors, with the gate voltages of the parallel pair of CMOS transistors connected to and controlled by a thermometer output signal, and the output of the pair of parallel CMOS transistors leading to and operatively connected to the inverter; in shorthand, this structure, can be called “delay-producing inverter operatively connected to CMOS transistors controlled by a thermometer output” or, even shorter, a “sub-gate delay logic array”.

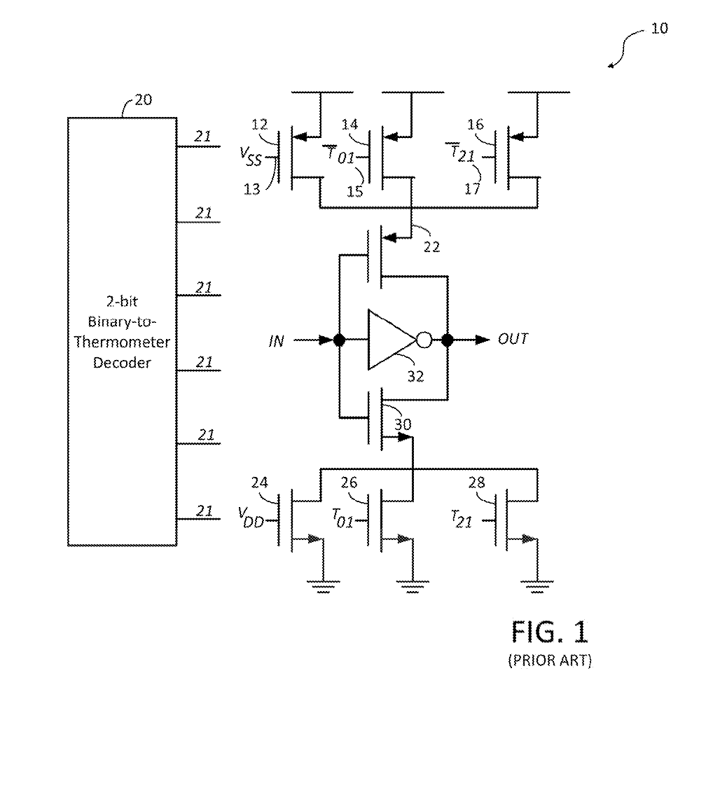

Operation of this delay inverter controlled by thermometer decoder is as follows. When there is the application of a suitable voltage control signal, which is thermometer coded, at gate inputs CN1, CN2, CN3, CN4, CN5, CN6, CN7 for the PFET transistors and gate inputs C1, C2. C3, C4, C5, C6, C7 for the NFET transistors, sufficient so that the MOSFET gate-source voltage exceeds some threshold value, the pMOS transistors 262, 264, 266, 268, 270, 272, 274 and nMOS transistors 261, 263, 265, 267, 269, 272, 273 will conduct maximum current via their drains into sources of CMOS transistors 253, 255, which can be shown empirically and theoretically to produce a minimum delay through the inverter 252. Conversely, turning off all PFET and NFET transistors at the top and bottom will produce a maximum delay through inverter 252, while turning off some pairs of PFET and NFET transistors, but keeping other pairs of PFET and NFET transistors on, will result in a delay somewhere between these two extremes. Consequently this sub-gate delay logic array structure, as in FIG. 1 (Prior Art) is a fine-tuning delay structure. The suitable voltage output for the thermometer coded control signal is output by a Binary-to-Thermometer Decoder that is called a control signal. The voltage levels for gate inputs CN1, CN2, CN3, CN4, CN5, CN6, CN7 for the PFET transistors and gate inputs C1, C2. C3, C4, C5, C6, C7 for the NFET transistors, comprising the control signal or voltage reference signal is thermometer (Unary coding) based and applied to both the PFET and NFET transistors. As can be shown by inspection, the opposite control values are always applied at the same time to the corresponding top and bottom transistors so the transistors are either both open or both closed at the same time for each gate input Ci or CNi, i=1, 2, 3 . . . 7.

Hence it can be seen that the fine grain sub-gate delay logic array structure shown in FIG. 3A can delay by a variable amount a signal that is input into IN′, passed through inverter 252, and output at OUT′, the degree of delay depending on the predetermined value of the thermometer based voltage reference signal, which can be termed a control signal, for the fine-tune grain sub-gate delay logic array of FIG. 3A. If the voltage signal is such that all transistors are instructed to be turned off, e.g. say for the seven PFET and NFET transistors, the signal “1111111” and “0000000” respectively (i.e., to turn off all the transistors one uses the signal “1111111” for PMOS and “0000000” for NMOS), then there will be maximum delay, some predetermined unit of time Delta TMax, from input IN′ to output OUT′. The next smaller delay from Delta TMax is when one of the seven transistors from the PFET transistors 262, 264, 266, 268, 270, 272, 274 and one of the seven transistors from the NFET transistors 261, 263, 265, 267, 269, 272, 273 are turned on to conduct current, e.g. with a signal “0000001” which creates a delay Delta TMax-(N*i), where i=1 and N is some small constant. The next smaller delay from this stage would be a signal such as “0000011” which would turn on two of the seven aforementioned transistors, and produce a delay Delta TMax-(N*i), where i=2 and N is some small constant. The next smaller delay from this stage would be a signal “0000111” where i=3, and so forth, until the smallest possible delay is when all seven transistors are turned on for both the PFET and NFET transistors, with a signal “1111111”. By this way the amount of delay produced by the inverter 252 in the fine-tune stage sub-gate delay logic array can be varied by a thermometer voltage control signal.

Glitch-free operation of the present invention has been found to occur when the DCDL structure disclosed herein is operated using thermometer coding for the control signals, and the thermometer coding is not changing from one value to another; hence the present DCDL is substantially glitch-free. This is true both for the fine-grain control blocks 12, 14 and the coarse grain control blocks 22, 24, 26, 28, 30. In FIG. 4, the inputs for the fine grain control blocks 12, 14, inputs C1-C7, which go to inputs CNi, Ci (with i=1 to 7) in FIG. 3A are in thermometer code. The fine-grain control blocks such as shown in FIG. 2A may also function akin to the coarse grain blocks shown in FIG. 2B when there is maximum delay in the sub-gate delay logic array 250, and when the inputs D1 or D2 (in FIG. 4) are set up with the proper predetermined signal. Finally, inputs D4, D5, D6, D7 in FIG. 4 are for the coarse tune modules 22, 24, 26, 28, 30 and must also be in thermometer coding.

Thus for the thermometer coding of the coarse tuning blocks 22, 24, 26, 28, 30, using the earlier notation, and if five bits are used for thermometer values, then a control thermometer value for minimum delay would be 10000, i.e. a delay path of A→22→Z. For the next larger delay, the thermometer value might be 11000, i.e. a delay path of A→22→24→22→Z. The next larger delay after this step might have a thermometer value of 11100, i.e. a delay path of A→22→24→26→24→22→Z. The maximum delay would be to traverse all the coarse tuning blocks, and might have a thermometer control voltage value of 11111, i.e. a delay path of A→22→24→26→28→30→28→26→24→22→Z. Of course one could elect to turn off the control modules altogether, e.g. with a thermometer value of 00000. The same is true for coarse delay that may be produced by the fine grain delay modules 12 and 14 (which can take two bits at D1, D2 in FIG. 4. for coarse grain control), which can be both turned off if no delay is required, or have one fine delay module turned on while the other is off, or have both turned on. Further, regarding the fine control modules, as explained herein, using the control signals at inputs C1-C7, which go to inputs CNi, Ci (with i=1 to 7) in FIG. 3A in thermometer code, the fine delay modules 12, 14 can delay a signal by a smaller time than the maximum coarse delay time for each module. Note due to various ways of representing thermometer values, a slightly different way than the above may be used without loss of generality, such as for example the representation of zero or taking the compliment of the zeros to equal ones and vice versa.

FIG. 3B shows an alternate embodiment sub-gate delay logic array fine-tune portion circuitry 250B to that of the FIG. 3A embodiment for the fine-tune portion circuitry 250 of the DCDL. This embodiment 250B provides nearly the same DCDL minimum delay as the fine-tune portion circuitry 250 of the DCDL of FIG. 3A, but is superior because it obtains even better maximum delay, due to the increased capacitance of the input pin A, therefore the overall DCDL range is increased. The fine-delay portion of the sub-gate delay logic array comprises an inverter 252A, comprised of CMOS transistors consisting of pFET transistor 253A, 253B, 253C, 253D, 253E, 253F and nFET transistor 255A, 255B, 255C, 255D, 255E 255F, forming an inverter 252A connected to a plurality of CMOS transistors in parallel at the tops and bottom having gates CNi or Ci (i=1, 2, 3, . . . ). These CMOS transistors consisting of pFET transistor 253A, 253B, 253C, 253D, 253E, 253F and nFET transistor 253B, 255B, 255C, 255D, 255E, 255F are connected in parallel to the output Z. One can call this embodiment of the fine delay module of FIG. 3B as comprising a sub-gate delay logic array comprising a delay-producing inverter having a plurality of parallel pFET and nFET transistors, in contradistinction to the fine delay module of the embodiment of FIG. 3A.

The controlling CMOS transistors comprise transistors 260A, 262A, 264A, 266A, 268A 270A, 272A, 274A (pMOS) and transistors 259A, 261A, 263A, 265A, 267A, 269A, 272A, 273A (nMOS), with the first two transistors 259A, 260A from the plurality of CMOS transistors being connected at their gates to Vdd and Vss, positive and negative (ground) voltage, respectively, and the remaining seven P-type MOSFET transistors 262A, 264A, 266A, 268A, 270A, 272A, 274A and seven N-type MOSFET transistors 261A, 263A, 265A, 267A, 269A, 272A, 273A having their gates connected to fine-stage decoder thermometer decoder outputs CN1, CN2, CN3, CN4, CN5, CN6, CN7 for the PFET transistors and fine-stage decoder thermometer decoder outputs C1, C2, C3, C4, C5, C6, C7 for the NFET transistors. The outputs (e.g. the drain) of these transistors are operatively tied to the inverter 252A, as shown. Hence, as shown in FIG. 3B, P-type MOSFET transistors 260A, 262A, 264A have their outputs tied to the source of P-type MOSFET transistor 253A, while the N-type MOSFET transistors 259A, 261A, 263A have their outputs tied to the source of N-type MOSFET transistor 255A. Likewise the other transistors, e.g. pFET transistor 266A has its drain tied to the source of pFET transistor 253B, while nFET transistor 265A has its drain tied to the source of nFET transistor 255B, and so on as shown in the diagram. Similarly there are connections between the various transistors 253A, 255A, 253B, 255B, 253C, 255C, 253D, 255D, 253E, 255E, 253F, 255F via connections such as shown as centrally extending line C15 (some lines not marked). The net effect of this configuration is that the maximum circuit delay is increased because the input pin A has bigger capacitance, though the minimum circuit delay is nearly the same as in the embodiment of FIG. 3A, due to the increased output drive strength.

The fine-delay structure described in the preceding paragraph and in reference to FIG. 3B can be deemed, for ease in description, as a structure comprising a delay-producing inverter bracketed by a pair of parallel CMOS transistors, with the gate voltages of the parallel pair of CMOS transistors connected to and controlled by a thermometer output signal, and the output of the pair of parallel CMOS transistors leading to and operatively connected to the inverter; in shorthand, this structure, can be called “delay-producing inverter operatively connected to CMOS transistors controlled by a thermometer output” or a “sub-gate delay logic array” for short.

Operation of the fine-tune delay of this fine-stage delay inverter, controlled by a thermometer decoder, is substantially the same as in the FIG. 3A embodiment. Thus, when there is the application of a suitable voltage control signal, which is thermometer coded, at gate inputs CN1, CN2, CN3, CN4, CN5, CN6, CN7 for the PFET transistors and gate inputs C1, C2. C3, C4, C5, C6, C7 for the NFET transistors, sufficient so that the MOSFET gate-source voltage exceeds some threshold value, the pMOS transistors 262A, 264A, 266A, 268A, 270A, 272A, 274A and nMOS transistors 261A, 263A, 265A, 267A, 269A, 272A, 273A will all conduct maximum current via their drains into sources of CMOS transistors 253A, 253B, 253C, 253D, 253E, 253F and 255A, 255B, 255C, 255D, 255E, 255F, which can be shown empirically and theoretically to produce a minimum delay through the inverter 252A from input A to output Z. Conversely, turning off all PFET and NFET transistors at the top and bottom will produce a maximum delay through inverter 252A, while turning off some pairs of PFET and NFET transistors but leaving other pairs of PFET and NFET transistors on will result in a delay somewhere between these two extremes. Consequently this sub-gate delay logic array structure, as in FIG. 1 (Prior Art) is a fine-tuning delay structure. The suitable voltage output for the thermometer coded control signal is output by a Binary-to-Thermometer Decoder that is called a control signal. The voltage levels for gate inputs CN1, CN2, CN3, CN4, CN5, CN6, CN7 for the PFET transistors and gate inputs C1, C2. C3, C4, C5, C6, C7 for the NFET transistors, comprising the control signal or voltage reference signal is thermometer (Unary coding) based and applied to both the PFET and NFET transistors. As can be shown by inspection, the opposite control values are always applied at the same time to the corresponding top and bottom transistors so the corresponding transistors are either both open or both closed at the same time for each gate input Ci or CNi, i=1, 2, 3 . . . 7.

Turning now to the Structured ASIC in which the DCDL of the present invention appears in, there in shown in FIGS. 6 and 7, a generalized floor plan architecture of the Structured ASIC chip 100, an ASIC having some pre-made elements that are mask-programmable or customized later by a customer rather than all at once as in a traditional ASIC, with the customization occurring by configuring via-configurable metal layers, preferably using just a single via layer. As best shown in FIG. 9A, the Structured ASIC 100 has a plurality of logic unit block modules 603 termed eMotif, that contain within, inter alia, via-programmable core logic cells 105, formed of MOSFET transistors. The logic modules 603 can be configured to perform any type of random logic, combinational logic or sequential circuit, and may cooperate with memory cells 610, forming a column interspersed between the columns of logic modules, with the logic modules 603 arranged in rows that cooperate with the memory cells 610 found adjacent to the logic. As can be seen from the figures, the memory cells and logic cells of the core alternate and repeat in layout in columns along the vertical north-south direction to the core. The memory is comprised of BRAM (Block RAM) in 512 kb×18 bits (with an extra bit for repair). The logic cell modules 603 and the memory blocks 610 together comprising the logic and memory core 715 of chip 100. The logic and memory alternate in a repeating pattern of vertically extending columns in substantially rectilinear or rectangle shaped core 715 as shown in FIGS. 6-7, with the columns aligned along a vertical, north-south axis or direction to the core, and repeating to form a scalable architecture. There is an via programmable IO region 630 on the left and right sides of the chip 100, servicing the core 715 comprising the logic cell modules 603 and the memory cells 610, and extending vertically north-south along the core 715 as shown. The via-programmable IO area comprising an IO sub-bank 630 extends to the left (west) and right (east) of the chip 100 and can access the core 715 as well as the other IO fabrics in chip 100, as well as communicate with the world outside the chip. In a preferred embodiment the area taken up by the total IO area, the memory and the logic each comprise roughly 30% of the total chip 100 area layout. BIST (Built-In Self Test) circuitry 625 exists in the IO area and may be controlled by a microcontroller or by an external tester. The BIST fabric 625 is for test and global connections and in one embodiment is three cells wide. Within the core 715 there is additional routing to connect the logic blocks 603 and memory cells 610 as need be, operatively connected to the IO circuitry at the periphery of the core 715.

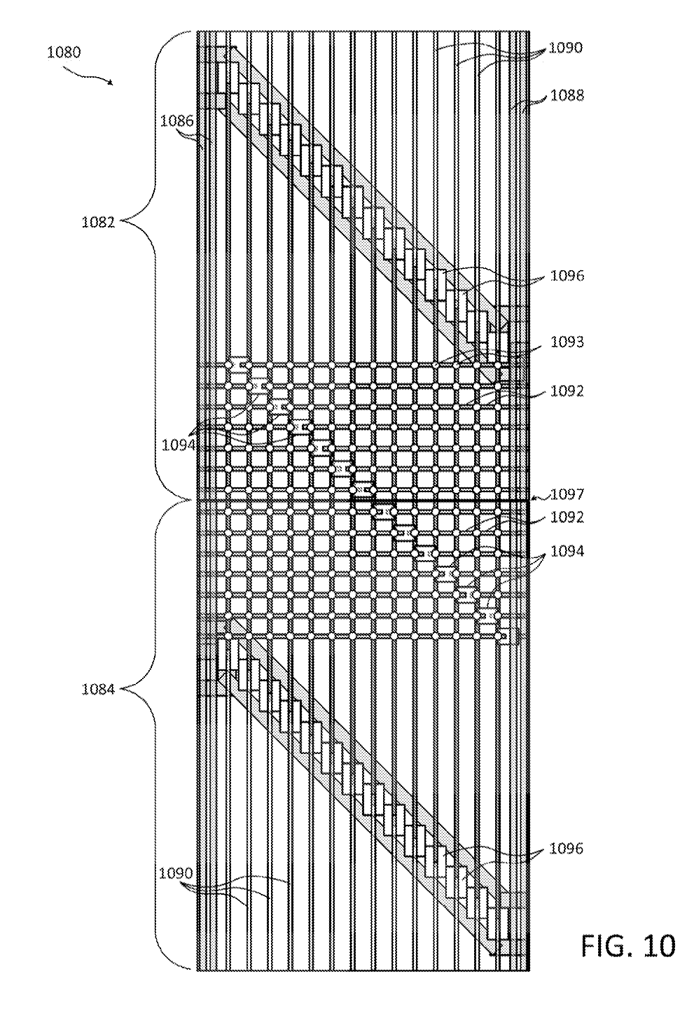

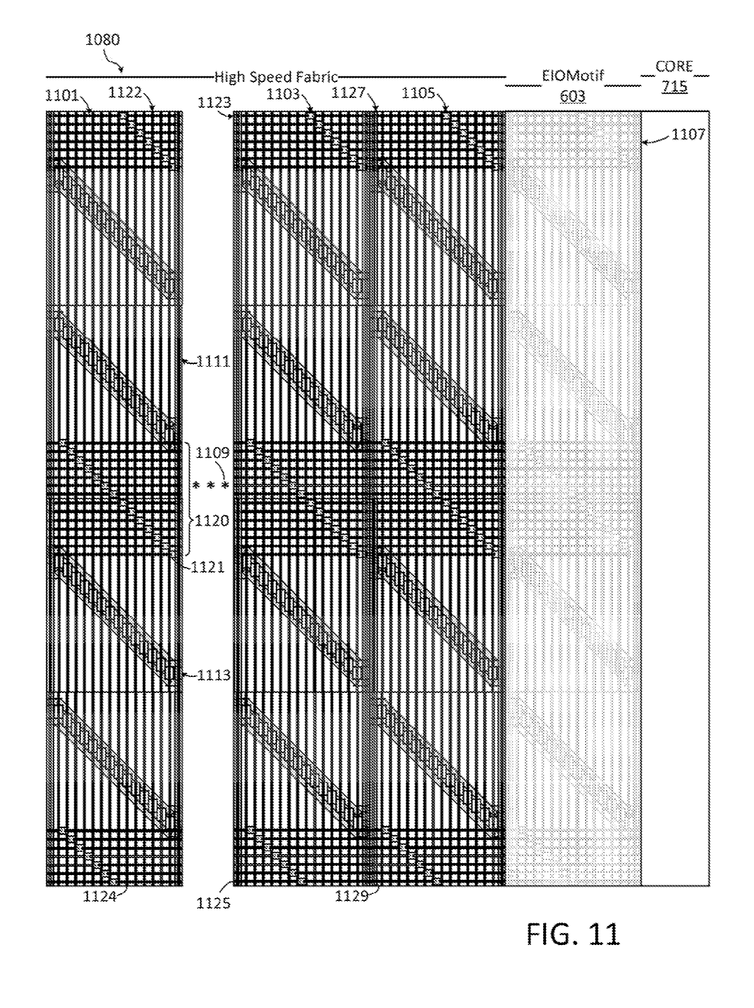

As shown in the figures, in particular FIGS. 6 and 7, the core 715 contains logic blocks 603 within it (logic blocks 603, termed eMotif, are best shown in FIG. 9A). On the outside of the core 715 there is, extending along the north-south direction, the first IO routing fabric 630 that is configurable through vias and connects the core 715 to logical pin IO and IO repeater areas for communication with the outside world. Thus the first IO routing fabric has a plurality of IOs comprising IO sub-bank 630 comprised of a plurality of IOs termed eIOs, each extending horizontally but collectively running on the left and right sides (north/south or vertical) of the core 715. As part of this first routing fabric is IO fabric 660, termed eIOMOTIF (best shown in FIG. 9), which lies in the space 620 between the first IO routing fabric 630 and the core 715. Technically this IO fabric 660 can be deemed part of the core 715 and is for communication between the logic in the core 715 and IO blocks 670. The first IO routing fabric 630 is slower than a second, high-speed IO routing fabric (not shown) having a faster data transfer rate for communication with high-speed IO such as high-speed SerDes (a serializer/deserializer integrated circuit transceiver that converts parallel data to serial data and vice-versa) and Multi-Gigabit IO (MGIO) block(s) 640, labeled “MGIO”. This second routing fabric (not shown in the figures) extends east-west at the top of the chip, between the core 715 and the MGIO blocks 640, to facilitate communication with the core 715 and the MGIO blocks 640, and may be operatively tied to the DCDL of the present invention. A third IO, third routing fabric (not shown is for communication with a microcontroller in the corner macro 650 and for testing of memory and logic in the core 715. Finally, a fourth IO routing (best shown in FIGS. 10 and 11), forming a second high-speed routing fabric, lies adjacent the first IO routing fabric, and in a north-south direction, for communication with the first IO routing fabric, and core 715.

All of these first second, third and fourth routing fabrics are distinct, and ordinarily the first and third routing fabrics dealing with IO and testing are not directly connected, but a designer may decide to operatively connected to one fabric to another and the core 715.

The first IO fabric of IO sub-bank 630, has four sub-banks 632, 634, 636, 638 on the left side of the Structured ASIC in FIG. 3A and five sub-banks 631, 633, 635, 637, 639 on the right side. Further, the Digitally Controlled Delay Line (DCDL) of the present invention would be found in-between the IO sub-bank 630 and the core 715, in the region 620, in the eIOMOTIF, and would run down the north-south (vertical) sides of the core 715.

As shown in FIGS. 6 and 7 in the upper left hand corner there is a corner macro 650 that contains a microcontroller or microprocessor block 652 for the Structured ASIC that acts to control, inter alis, JTAG (boundary scan test) logic that is part of the third routing fabric for the core 715. The 32 bit microcontroller block 652 is used for a plurality of functions including but not limited to testing of memory and logic, including BIST (Built-In Self Test) testing, and fuse/anti-fuse support for any logic that supports this functionality, such as eFuse block 654, addressing memory, such as memory blocks/cells 610, and initialization and configuration of the chip 100. The microcontroller block 652 may also, on-the-fly, configure IP in core 715, through the fabric in the core 715 and/or through JTAG (e.g., IEEE 1149.1 Standard Test Access Port and Boundary-Scan Architecture) ports. The microcontroller 652 can set up test paths inside the chip for BIST and/or scan-chain testing for testing memory and/or logic in core 715, in conjunction with test circuitry and pathways including the network-aware IO fabric (not shown but primarily having network aware logic primarily lying on the top and bottom of the core 715). The microcontroller can also set impedance dynamically and digitally in the SerDes of the present invention, as well as any dynamically configurable IO components, through access to a delay tap and perform other such customization of the Structured ASIC through access to the routing fabric.

The Structured ASIC chip 100 of the present invention has eight signal metal layer (M1-M8, with one of those eight layers being customizable or via configurable by the customer of the Structured ASIC and the others being fixed prior to customization by the customer), and three metal layers M9/M10/M11 for power distribution.

In FIGS. 6, 7 and 8, the plurality of IO areas are reserved on the chip of the Structured ASIC for Input/Output (IO), called IO sub-bank blocks, generally block 630 (IO routing fabric 630), have inside them horizontally extending individual IO blocks 670 termed eIO, these blocks being via-configurable IO blocks, and the entire collection of these IO comprising, due to package restrictions, twenty-eight eIO cell blocks in a preferred embodiment, but in general any number may be employed. These eIO cells are via-programmable by a customer employing the Structured ASIC, in order to make the IO accessing the core 715 conform to various standards for accessing the contents of the Structured ASIC. By way of example, two eIO cells can make two single-ended IOs or one differential IO. The eIO cells support different I/O standards requirements during user mode, as well as JTAG and TEST mode. Some of the interface standards supported by via-programmable eIO cells include, but are not limited to the following interface standards, in various voltages as required by the standards: LVCMOS, PCI, PCI-X, SSTL-2 class 1, SSTL-2 class 2, SSTL-5 class 1, SSTL-5 class 2, SSTL-8 class 1, SSTL-8 class 2, SSTL-12 class 1, SSTL-12 class 2, SSTL-15 class 1, SSTL-15 class 2, SSTL-18 class 1, SSTL-18 class 2, SSTL-35 class 1, SSTL-35 class 2, HSTL12 class I, HSTL12 class II, HSTL15 class I, HSTL15 class II, HSTL18 class I, HSTL18 class II, ONFI 1.8V DDR, ONFI 3.3V SDR, LVDS, RR-LVDS, Extended LVDS, Sub-LVDS, RSDS, Mini-LVDS, Bus-LVDS, single-ended IOs, differential IOs and TMDS drivers. In addition, some of these IO standards require a delay in the IO signal such as can be provided by the DCDL of the present invention.

IO path areas for power related macros and sub-bank routing include areas for power related macros and subbank routing, and to logical pin IO repeater areas, where any IO signal may be buffered and/or repeated or transmitted for eventual transmission to the logical physical pins that contact the Structured ASIC chip 100 at the periphery, for input/output to external signals. The eIOMOTIF boundary region 660 can contain logic to configure the eIO cell blocks 670, and is also tied to the DCDL blocks, and the eIOMOTIF boundary region 660 can be considered part of the core 715.

For the Structured ASIC chip 100 there are several IO sub-bank routing blocks 630, as can be seen in FIG. 8, with a plurality on one side and the other side of core 715, which contain within them PLLs and DLLs, as need be, as indicated in FIG. 8 as “PPL”, and “DLL”. PLLs have eight-phase rotators 663. Each PLL can produce multiple clock signals and up to eight-phases per clock signal; the eight-phase rotators 663 are muxes that select one of these eight phases with a minimum of glitches, useful for high-speed SerDes. EDT (Engineering Design Test) areas 671 and marked as “EDT17” are test logic pins for use by a third party provider, Mentor Graphics, for testing of the chip using scan-chains, as is known per se. On the IO sub-bank 630 there may also be blocks for power clamps, POR (Power On Reset), and voltage reference related blocks. IO path areas for power related macros and sub-bank routing include the area labeled as “Area for power related macros and subbank routing” in FIG. 8, and then to the logical pin 10 repeater areas 674, where any IO signal may be buffered and/or repeated or transmitted for eventual transmission to the logical physical pins that contact the Structured ASIC chip 100 at the periphery, for input/output to external signals.

As best shown in FIGS. 9A and 9B, the DCDL of the present invention, as shown in FIG. 4, is placed in the eIOMOTIF IO fabric 660 along the north-south periphery of core 715. Roughly half of the fabric 660 is comprised of DCDL blocks 910, aligned with the rows formed of eMotif logic modules 603, with eight blocks of DCDL blocks 910 for each eMotif logic module 603, as shown in FIG. 9A. In preferred embodiments there may be over 84 k to 1.7M eMotif logic modules 603 in chip 100. Eight DCDL blocks 910 were chosen in a preferred embodiment to give the user of the Structured ASIC 100 maximum flexibility in things like adjusting the global clock signal, PLL/DLLs and IO signals, with IO such as found in routing fabric eIOMOTIF 660. Thus as shown in FIGS. 7, 9A there is the IO fabric 660 in which the DCDL appears embedded in as DCDL blocks 910, that in a preferred embodiment has eight DCDL modules 910 appear along-side of each eMotif logic module 603, and cooperating with an eMotif logic unit block 603 used for supporting random logic in the Structured ASIC of the present invention.

As best shown in FIG. 9A, regarding eMotif block 603, eight full adders 904 surround each four-by-four block 906 of tiled pattern logic block cells 105, that, together with the clock macro 615′ and associated flip flops 911, form a cross-shape, and comprise the eMotif eCELL Matrix 603. There are 32 full adders 904 for each eMotif eCELL Matrix 603, as shown. Full adders are often used in addition and complex multiplication of the kind performed by communications ASICs and in multiplexers. The full adders 904 can be embedded inside the cells 105 rather than outside as shown. The contents of the cells 105 in eMotif 603 may be any kind of logic such as a CLB, though in general the cells 105 comprise transistor based logic. Furthermore these cells 105 may be made of FET transistors manufactured by a CMOS process in the 28 nm or smaller lithographic node. Conventional D flip-flops 911 are present in eMotif 603 and can be used in registers and to hold state information; in general any type flip-flops may be used. An optional external routing buffer 913, that may also be incorporated into the individual logic cells 105 of the eMotif eCELL Matrix 603 itself, is for buffering routing paths in the eMotif eCELL Matrix 203. A clock macro 615′ in the center of the eMotif eCELL Matrix 603 has routing buffers 913 for efficiently distributing one or more clock signals received from clock trees throughout the chip, as well as providing a local clock signal for the eMotif eCELL Matrix 203. The buffers 913 and D-flip-flops 911 form a distinctive cross shape in the eMotif eCELL Matrix 603, centered about the clock macro 615′. Suitable connecting traces and fabric (not shown) connect the blocks shown in eMotif module 603. Further, high-speed D flip-flop blocks, also known as data flip-flop blocks, four to six D flip-flops per block, can be provided at D flip-flop blocks 952 (called eDFF) for connection to the core logic, and which are also connected to the routing fabric and clock bus lines 920.

As best shown in FIG. 9B, in cross-bar switch 915, clock bus 920B, comprising thirty-two signal wires in a preferred embodiment, provides for global clock tree routing (part of these thirty-two wires from a core clock bus come out of the plane of the paper from another layer or layers, i.e., metal layers, and hence cannot be shown in FIG. 9B in their entirety), to cross at cross bar switch area 915. Another eighteen vertically extending shielded wires for the clock are shown at routing fabric and clock bus lines 920, which cooperate with the eIOCLOCK clock macro 615. The eIOCLOCK clock macro 615 has three input pathway lines and one output pathway line comprising a plurality of eighteen lines. The three input pathway lines are from the north (top), west (left) and south (bottom) sides, and comprise clock lines from the routing fabric and clock bus lines 920 for both the north and south directions, and fourteen lines from a high-speed fabric having connector HS bus connector 935, that may connect to DLLs/PLLs. eIOCLOCK clock macro 615 is for routing signals, receiving as input lines from high-speed HS bus Connector 935 (which can connect to a high-speed fabric that services for example PLL/DLLs) from the left, routing fabric and clock bus lines 920 from the top and bottom, and outputs 14 lines to the right. Clock macro eIOCLOCK macro 615 contains a cross bar internally to aid in routing. At cross-bar switch 915, the lines from a high-speed HS bus connector 935 and the clock macro 615 cross with the thirty-two wires of the global clock, core clock bus tree that come out of the plane of the paper for further routing to the eMotif 603. The routing fabric and clock bus lines 920 can be tied to the eIOMOTIF 660 and consequently DCDL blocks 910 such as shown conceptually with lines 922, for the DCDL blocks to affect the clock signal. A high-speed fabric bus (fourteen wires) 930, which typically communicates with DLLs and PLLs, as well as eIO cells as explained herein, is connected to a high-speed bus connector 935 which in turn communicates with the clock lines via cross-bar switch 915 and can further be operatively connected to the routing fabric and clock bus lines 920 and DCDL blocks 910. The cross-bar switch 915 has and can interconnect in a matrix switch from the following signal lines: in the east-west direction, fourteen lines that ultimately come from the HS bus connector 935 (these lines are routed past the eIOCLOCK clock macro 615 and not through it), the output lines, traveling east, of eIOCLOCK clock macro 615, and, running vertically, the thirty-two signal wires of the core clock bus 920 (which enter from points that come out of the plane of the paper from a metal layer and entering the plane of the paper in the figure from a substantially orthogonal direction) to enable any vertical line to be connected to any horizontal line. The output of the cross-bar switch 915 extends horizontally into the eMotif logic module 603.

FIG. 10 is a more detailed schematic close up of another high-speed routing fabric 1080 of the present invention (a fourth routing fabric) used to communicate with high-speed devices. It should be noted that this fourth routing fabric high-speed routing fabric 1080, running vertically north-south on chip 100, appears in structure very similar to the second routing fabric at the top of the chip, which runs horizontally (east-west), but the two high-speed fabrics are different in application. The high-speed fabric 1080 connects IO logic block 603 and memory cells 610 of core 715 of the Structured ASIC chip 100 with the DCDL, clock, IO region 630 and memory or communication interfaces (e.g. DDR SDRAM, double data rate synchronous dynamic random-access memory), fits in space 620 in-between the IO region 130 and eIOMOTIF 160, running vertically, hence the fabric 1080 fits along the north-south extending vertical sides of the substantially rectilinear chip 100. In addition high-speed (HS) routing fabric 1080 may communicate through an interface with any high-speed memory such as DDR found outside the chip, the clock network of chip 100, the PLLs/DLLs of the first routing fabric and may exist on any of the metal layers. The high-speed third routing fabric 1080 may be connected to the high-speed fabric bus 930 (fourteen wires in FIG. 9B), which typically communicates with DLLs and PLLs in IO sub-banks 630. The high-speed routing fabric 1080 is shielded or double shielded and balanced by its nature, as explained further herein, so any delay from one point to any destination of its branch has the same delay, to allow proper signal and clock routing by its very construction. The high-speed routing fabric 1080 of FIGS. 10, 11 can form a type of crossbar switch, accepting multiple inputs and giving multiple outputs, as explained below, and in a preferred embodiment giving a balanced binary tree having at least two nodes at each branch.

As best seen in FIG. 10, the HS routing fabric is composed of a plurality of units, such as HS units 1082, 1084, with unit 1084 simply being unit 1082 rotated by 180 degrees. Each eMotif logic block 603 will have four of such HS units operatively abutting it, servicing it. Extending vertically, there may be hundreds of such HS units, depending on the number of eMotif logic blocks 603 present. The HS units have on both the left and right sides vertically extending power and ground lines 1086, 1088, which are somewhat larger in diameter than the vertically extending signal wires or lines remaining, fourteen of which are shown, which convey a signal, such as a clock signal or any other high-speed signal. Another plurality of horizontally extending wires or lines 1092 also are for carrying signals, and can be made to electrically connect to any vertically extending signal line 1090 by filling a via, in a via programmable manner, such as via 1093, which can be filled or open, as the designer sees fit, to connect the vertically extending signal line 1090 to the horizontal extending signal line 1092. The vertical and horizontally crossing wires in the HS units form a planar network where they intersect.

A plurality of planar connection blocks or connectors 1094 can be made to connect what is normally an open circuit at each of the lines 1092 in which these connectors are placed inline with the lines 1092. By filling the connectors, preferably in a via-configurable manner, to close, the lines 1092 go from an open circuit to a closed circuit state and conduct a signal. Once the connectors 1094 are closed there can be electrical conduction in the horizontally extending wires 1092. The via programmable planar connection blocks 1094 are placed in a diagonal line as shown, to provide a better layout. Inverters or inverting buffers 1096 are placed along a diagonal line to create a balanced signal, facilitate the signal, and connect to the horizontally placed wires 1092. The distance of each inverter 1096 from the connectors 1094 are equally spaced so any signal that branches from the connector takes the same amount of time to traverse one branch leading up as a signal does to traverse the other branch leading down. The HS units 1082, 1084 have a planar network end 1097 and an open end 1098. To form a planar network, as shown, the two planar network ends of HS units 1082, 1084 are abutted end to end. The area of intersecting vertical and horizontal signal wires 1090, 1092, together with associated programmable vias, inverters and planar box connection blocks, form a fourth routing fabric switch.

FIG. 11 shows the HS units of the high-speed routing fabric 1080 arranged in columns next to a single eMotif logic block 603. Thus, as shown, four HS units are shown arranged in each column, such as a plurality of vertically extending (north-south) columns such as HS columns 1101, 1103, 1105, 1107 (with ellipses 1109 indicating more columns may be present, not shown). In addition, there are four HS units shown because it is assumed that there is just one eMotif logic block 603 abutting the last column 1107, but in fact in a chip each eMotif block would abut four such HS units and many hundreds of such eMotif blocks 603 would be present—in one preferred embodiment over 1.77M such eMotif blocks are present. In one preferred embodiment eight such HS columns exist on chip 100. The last column, 1107, may actually lie underneath the eIOMotif boundary routing region 660 for connection to the eMotif 603. The two middle HS units in each column form the main planar network, such as HS units 1111, 1113. Each eMotif block 203 would have in a preferred embodiment eight such HS columns in the horizontal direction and many HS units in the vertical direction.

The high-speed routing fabric of FIGS. 10, 11 is ideally suited for clock trees in a balanced manner. For example, a signal travels along the horizontal direction and has to be split, as is common in a clock tree, into two equal branches that are balanced. This occurs at any planar connector 1094 or at any via 1093 between the vertical and horizontal lines 1090, 1092. At each column at each planar connector 1094 or at any via 1093 a signal may be split into two, to travel in two paths, hence in each column there can form any number of branch nodes of a binary tree. With eight columns, and sufficient connections, a signal may be split into 2̂8 power or 256 levels or branches. This is ideal for a clock tree.

An illustration of the myriad connections that may be possible given the structure of FIGS. 10, 11 may be given, with the understanding a skilled designer can come up with many more configurations from the teachings herein. Hence, by way of example, in FIG. 11, to form a clock tree of say eight levels, a signal would come in at a horizontal planar connector line, e.g. line 1121, into the center planar connection region 1120 of the HS fabric, feeding the first planar connector of HS units 1111 and 1113 of the first HS column 1101 upon which the signal is split into two by the first planar connector of the column 1101 (e.g., the farthest to the left and top row planar connector) to travel along a vertically extending line 1090, and is sent to each of the ends of the column, at ends 1122 and 1124, upon which the signals, through suitable connections at these ends (these connections being via-programmable), travels along a horizontally extending line 1092 to feed into either the next column at ends 1123 and 1125 (assuming for the sake of this example there are no intervening columns such as indicated by the ellipses 1109), or, into another vertically extending line 1092 at the same column (as there are many such lines given each eMotif cell 603 abuts eight such columns in a preferred embodiment, and there may be several hundred thousand such eMotif cells. At that point the two signals again move to a center planar connection region 1120, such as for example the second HS column, HS column 1123, or an adjacent first HS column from another eMotif cell, where there are now two signals on two lines, that are split into four signals. Now there are four signals being sent to the ends 1123, 1125 of the HS units of the high-speed fabric 1080, and these four signals would be connected, through via-programmable connections, to the third column, HS column 1105, or to the same column in an adjacent eMotif cell 603. These four signals would now be each split into two signals to form eight signals, at the center planar connection region 1120 of the third column, HS column 1105, or at the center planar connection region of the same column in an adjacent eMotif cell 203. At this point you would have eight leaves of this tree. This process can continue up until all eight columns (in a preferred embodiment) are exhausted, so you can have 256 levels of a balanced binary tree in this manner (2̂8=256).

In an actual design the more general case is to have several trees in parallel, each using different lines in the high-speed fabric 1080. Hence one has say eight entry points on the left hand side of the HS fabric 1080 which runs down the north-south side of the chip 100 and eight destination points running into the core 715 of the chip 100, all handled by the HS fabric working with the eIOMOTIF fabric 660, and running into the boundary eMotif cells 603. Eight entry points are often used with phases in PLL/DLLs in the chip 100. Multiple entry points are also used with DDR SDRAM interfaces, as explained further herein. The routing delay will be the same for any and all of these entry and destination points due to the balanced nature of the HS fabric 1080.

The HS fabric 1080 abuts a single eMotif 203 module on one side as shown in FIG. 11, but it can support in fact support three columns of such eMotif modules, which are aligned in rows (the other two eMotif modules to the right of eMotif module 603 in FIG. 11 not shown for example, which lie in the same row as the HS fabric 1080). Thus the unit of the HS fabric 1080 shown in FIG. 11 can support three eMotif cells in the same row, and so on (as the HS fabric 1080 extends in the vertical direction in a columnar form), so the HS fabric 1080 can support three columns of eMotif cells.

The HS fabric 1080 can be operative connected to the eIOMOTIF fabric 660, which is tied to both the eMotif cell modules 603 and the eIOs of IO sub-bank 630. The HS fabric and the trees that are capable of being built in it can support the global clock tree for chip 100.

The HS fabric 1080 can also support an interface for memory, such as DDR, (DDR SDRAM) and any associated logic for this interface to DDR (the actual DDR memory itself is found outside the chip 100). The HS fabric 1080 also supports eIOs and DLLs/PLLs in the IO sub-bank 630, including but not limited to single-ended IOs and differential IOs found therein. A byte of DDR interface includes data for eight single-ended IOs, a differential IO for any synchronization strobe, and data for the PLL/DLL. This DDR interface is readily implementable from the hardware of the present invention, despite the strict requirements for skew, cross-talk and balancing, by utilizing the eIOMOTIF fabric, and eMOTIF modules. Using the hardware one could even construct a hard macro to achieve the functionality of the DDR interface. Using the present invention any interface including but not limited to any serial data streams, serializers/deserializers, network interfaces, and other data interfaces.

Regarding the present invention, it is important to reiterate that the floorplan of the Structured ASIC is providing an infrastructure for a customer to use to build some sort of circuit of value to the customer, primarily through programmable vias. The number of circuits that can be built, and the various interconnections between the elements of the Structured ASIC, is a large set. Any number of connections may be made as can be appreciated by one of ordinary skill in the art from the teachings herein.

The architecture of the present invention has been found to not produce clock glitches when control signals are in thermometer coding as taught herein, and have a wide range of operation across various process, voltage and temperature (PVT) variations.

A designer using the architecture for a DCDL of the present invention can thus make various delays, from fine to coarse, over a wide range. Hence the present invention achieves glitch free and scalable range DCDL by combining in a serial, pipeline stage manner a sub-gate delay fine stage structure for DCDL in combination with a coarse state structure, as shown in the figures, as long as thermometer coding is employed for the control code, and the control code does not change during a transition of any data signal such as a clock signal. Hence the present invention is substantially glitch-free.

Placement of the blocks that comprise the DCDL of the present invention are shown in FIG. 5, which is the floor plan for layout of the Delay Tap, comprising the fine-tune delay stage, the coarse-tune delay, and decoders for both. Placement of these DCDL blocks may be embedded in the eIOMOTIF fabric 660. Each delay line may be composed of eight independent Delay Taps as per DCDL macros 910, that can be operatively connected in series, as shown in FIG. 9 and incorporated into network-aware IO fabric eIOMOTIF 660. In the blocks the fine delay stage block 224 is laid next to the coarse delay stage block 226. Fine stage decoder block 228 is a Grey-to-Thermometer decoder, as is known per se, and controls the DCDL of the fine delay stage block 224 (as disclosed herein), while coarse stage decoder block 230 controls the DCDL of the coarse delay stage block 226 with another Grey-to-Thermometer decoder (known per se). The decoders 220, 222 shown in FIG. 5 are glitch free Grey-to-Thermometer code decoders when used in the present architecture, and it can be shown both theoretically and empirically via simulation that a 4-to-15 Grey-to-Thermometer decoder in the present invention will produce a clock glitch free output. Thus as shown in FIG. 9 each “delay line” next to the eMotif module 603 may be composed of eight independent Delay Taps 910, which correspond to the fine and coarse delay modules as specified herein and their decoders, and as laid out in blocks as shown in FIG. 5.

As mentioned, the controller for the DCDL is found in the core 715, and has its own control logic, with signal lines from the DCDL controller in core 715 sent to the DCDL found in the eIOMOTIF fabric 660 as an encoded Grey code signal to save space on the chip 100, since Grey codes are more compact than thermometer value codes and require fewer signal lines or bandwidth to transmit. Thus the thermometer values used in the DCDL are actually originally Grey code values in the DCDL controller found in core 715 that are converted to thermometer code by the DCDL Binary-to-Thermometer decoder. This saves signal lines for transmission from the DCDL controller to the DCDL circuit, since for example four bits using a decoder can produce 16 bits of instructions (2̂4=16). In actual practice eight bits in Grey code are sent by a DCDL controller found in core 715 and decoded by the decoders as shown in FIG. 5, to produce thermometer code as explained herein. In one preferred embodiment the eight bits sent by the DCDL controller comprise 4 bits intended for coarse delay stage modules and 4 bits intended for the fine-delay stage modules, and from these four bits the fine delay decoder 224 and coarse delay decoder 225 produce 15 bits of thermometer value instructions for the coarse stage modules 22, 24, 26, 28, 30 and 14 bits for the fine stage modules 12, 14 (7 bits for each of the two fine stage modules 12, 14). In general the number of bits sent may be more or fewer depending on how many coarse and fine stage modules are being employed, and are not limited to the numbers shown herein in a preferred embodiment.

Regarding the present invention, it is important to reiterate that the floorplan of the Structured ASIC is providing an infrastructure for a customer to use to build some sort of circuit of value to the customer, primarily through programmable vias. The number of circuits that can be built, and the various interconnections between the elements of the Structured ASIC, is a large set. Thus by definition not every conceivable variation of interconnection that is possible using the architecture of the present invention can be readily described in a single document of reasonable size, but the essential features are described in the present application, as can be appreciated by one of ordinary skill in the art.

Regarding manufacture of the present semiconductor circuit comprising a DCDL in a via-configurable Structured ASIC, it may be manufactured on a 28 nm CMOS process lithographic node or smaller and having feature sizes of this dimension or smaller. The method of manufacturing the ASIC may be as the flow was described herein in connection with an ASIC and/or Structured ASIC; and the DCDL would be a block of logic within that ASIC. The DCDL as well as the floor plan of the Structured ASIC of the present invention are manufactured using a CMOS semiconductor process using NFET/nMOS and PFET/pMOS transistors, which includes a via-configurable logic block (VCLB) architecture. VCLB configuration may be performed by changing properties of so called “configurable vias”—connections between VCLB internal nodes. The configurable vias that are used to customize the chip at a plurality of metal layers, and preferably between two metal layers with a single via layer, and are changed by the customer that deploys the Structured ASIC. Thus it is possible that in this design the customizable metallization layers may be reduced to a few or even a single via layer where the customization is performed, see by way of example and not limitation the patents to the present assignee to this invention, eASIC Corporation, U.S. Pat. No. 6,953,956, issued to eASIC Corporation on Oct. 11, 2005; U.S. Pat. No. 6,476,493, issued to eASIC Corporation on Nov. 5, 2002; and U.S. Pat. No. 6,331,733, issued to eASIC Corporation on Dec. 18, 2001; all incorporated herein by reference in their entirety. Further, a single via layer could be customized without resorting to mask-based optical lithography, but with a maskless e-beam process, as taught by the '956 patent.

Modifications, subtractions and/or additions can be applied by one of ordinary skill from the teachings herein without departing from the scope of the present invention. For example, though the invention discusses the architecture of a DCDL but does not make any claims on how to configure the DCDL to achieve control, e.g. to construct a first-order DCDL, or a second-order DCDL. Constructing such a DCDL is only limited by the imagination of the designer using the architecture of the present invention. As another example, both in the fine-tune stage and the coarse-tune stage the delay elements are inverters, but this term should be thought of as synonymous with any sub-gate element that is capable of delaying a signal; inverters are generally favored because the amount of delay produced is relatively small, hence a more fine resolution of delay is possible by the cumulative addition of such delays, but in general any electronic structure that produces delay can be thought of as functioning as and synonymous with the delay-producing inverter taught herein. Thus the scope of the invention is limited solely by the claims.

It is intended that the scope of the present invention extends to all such modifications and/or additions and that the scope of the present invention is limited solely by the claims set forth below.

We claim:

1. A Digitally Controlled Delay Line (DCDL), comprising:
a module for the coarse delay of a signal having an input and an output;
a module for the fine delay of a signal, having an input and an output;
wherein a signal is capable of being delayed by the fine delay module for a period of time less than the period of time the signal is capable of being delayed by the coarse delay module.

2. The DCDL according to claim 1, wherein:
the fine delay module is in series with the coarse delay module, with the output of the fine delay module input into the input of the coarse delay module; and,
the coarse delay module comprises a delay producing inverter.

3. The DCDL according to claim 2, further comprising:
a circuit for producing a thermometer coded signal output.

4. The DCDL according to claim 3, wherein:
the fine delay module comprises a sub-gate delay logic array comprising a delay-producing inverter, the inverter having a plurality of parallel pFET and nFET transistors.

5. The DCDL according to claim 3, wherein:
the fine delay module comprises a sub-gate delay logic array comprising a delay-producing inverter.

6. The DCDL according to claim 5, further comprising:
the circuit for producing thermometer coded signal output comprises a binary-to-thermometer decoder for outputting the thermometer codes signal output, operatively connected to the sub-gate delay logic array comprising the delay-producing inverter.

7. The DCDL according to claim 6, wherein:
a plurality of coarse delay modules connected in series with one another, the output of one coarse delay module input into the input of another coarse delay module;
and,
the plurality of coarse delay modules comprise two inputs, and two outputs, an inverter for producing delay of a signal input into the coarse delay module, and a mux for selectively controlling the signal path for the signal input, to either one of the two outputs.

8. The DCDL according to claim 7, further comprising:
a plurality of fine delay modules connected in series with one another so the output of one fine delay modules is connected to the input of the other fine delay module;
and,
further comprising a second binary-to-thermometer decoder outputting a second thermometer output signal, the second decoder operatively connected to each of the coarse delay modules, the mux for each of the coarse delay modules employing the second thermometer output signal to control the delay of the signal input.

9. The DCDL according to claim 1, further comprising:
the fine delay module is in series with the coarse delay module, with the output of the fine delay module input into the input of the coarse delay module;
a plurality of coarse delay modules connected in series with one another, the output of one coarse delay module input into the input of another coarse delay module;
and,
the fine delay module comprises an inverter operatively connected to the drain of a plurality of nMOS and pMOS transistors in parallel, having their gates controlled by a voltage control signal that is thermometer code.

10. The DCDL according to claim 9, further comprising:
the plurality of coarse delay modules each comprise two inputs, and two outputs, at least one inverter for producing delay of a signal input into the coarse delay module and connected to one of the two outputs, and a mux for controlling the signal path for the signal input, to either one of the two outputs; and,
a binary-to-thermometer decoder outputting the thermometer code voltage control signal for the fine delay module, the signal sent to the gates of the plurality of transistors in parallel, through which the amount of delay produced by the inverter can be varied.

11. The DCDL according to claim 10, further comprising:
a second binary-to-thermometer decoder outputting thermometer code as a voltage signal for the plurality of coarse delay modules, the muxes of each coarse delay module receiving as input the thermometer code; and,
a plurality of fine delay modules, connected in series.

12. The DCDL according to claim 11, further comprising:
a structured application specific integrated circuit (Structured ASIC) comprising a substantially rectilinear core comprising memory cells and logic cells, a first IO comprising a plurality of IO blocks along the sides of the core, operatively connected to the core, the first IO comprising a first routing fabric, a second IO comprising a high-speed routing fabric operatively connected to the core; wherein, the first routing fabric aligned to the sides of the core and connected along the north-south, vertical sides of the core;
the first routing fabric is configurable through vias in the Structured ASIC, and connects the core to logical pin IO repeater areas;
the memory cells and logic cells of the core alternate and repeat in layout in columns along the vertical north-south direction to the core; and,
wherein the DCDL is operatively connected to the first routing fabric and is found next to the core, to provide delay to any signal accessing the core.

13. The DCDL according to claim 12, further comprising:
a fourth routing fabric comprising a high-speed routing fabric aligned to the sides of the core and connected along the north-south, vertical sides of the core;
the fourth routing fabric comprises a fourth routing fabric switch forming conductive paths that travel vertically and horizontally to the core; and,
the fourth fabric switch contains vias, inverters and planar box connection blocks connected to the vertically and horizontally traveling conductive paths of the switch.

14. The DCDL according to claim 13, further comprising:
a plurality of the fourth routing fabric switches arranged in columns in the fourth routing fabric, the plurality of columns operatively electrically connected to one another through programmable vias; wherein,
a binary tree of connections is employed in the fourth routing fabric in the conductive paths, with each column forming a branch node of the binary tree of connections; and,
wherein the tree of connections forms a balanced tree.

15. The DCDL according to claim 12, wherein:
the first routing fabric comprises via-configurable 10 blocks that are configurable to conform to the one of the following interface standards selected from the group consisting of LVCMOS, PCI, PCI-X, SSTL-2 class 1, SSTL-2 class 2, SSTL-5 class 1, SSTL-5 class 2, SSTL-8 class 1, SSTL-8 class 2, SSTL-12 class 1, SSTL-12 class 2, SSTL-15 class 1, SSTL-15 class 2, SSTL-18 class 1, SSTL-18 class 2, SSTL-35 class 1, SSTL-35 class 2, HSTL12 class I, HSTL12 class II, HSTL15 class I, HSTL15 class II, HSTL18 class I, HSTL18 class II, ONFI 1.8V DDR, ONFI 3.3V SDR, LVDS, RR-LVDS, Extended LVDS, Sub-LVDS, Mini-LVDS, Bus-LVDS, single-ended IOs, differential IOs, TMDS drivers and RSDS.

16. A method for constructing a Digitally Controlled Delay Line (DCDL) in a programmable Structured ASIC, comprising the steps of:
forming in silicon employing CMOS transistors a Digitally Controlled Delay Line (DCDL) block, comprising a module for the coarse delay of a signal, and a module for the fine delay of a signal; the coarse delay module having an input and an output, the fine delay module having an input and an output, wherein a signal is capable of being delayed by the fine delay module for a period of time less than the period of time the signal is capable of being delayed by the coarse delay module; and,
forming the fine delay module to be in series with the coarse delay module, with the output of the fine delay module input into the input of the coarse delay module;
controlling the fine delay module of the DCDL by a control signal that is a thermometer coded signal; and,
wherein the delay produced of the signal is substantially glitch-free.

17. The DCDL according to claim 16, further comprising the steps of:
forming the fine delay module into a sub-gate delay logic array.

18. The DCDL according to claim 17, further comprising the steps of:
forming a plurality of coarse delay modules in series with one another and connected in series with the fine delay module.

19. The DCDL according to claim 18, further comprising the steps of:
forming the coarse delay module into a gate-delay device that delays a signal input into it by diverting the signal either one of a first signal path and a second signal path;
controlling the coarse delay module with a second thermometer coded signal that determines the delay produced by the coarse delay module;
providing a DCDL controller circuit that outputs a binary Grey code signal;
providing a Binary-to-Thermometer decoder that inputs the binary Grey coded signal and outputs the first thermometer coded signal;
providing a second Binary-to-Thermometer decoder that inputs the binary Grey coded signal and outputs the second thermometer coded signal; and,
providing a second fine delay module operatively connected in series with the first fine delay module.

20. A DCDL for a Structured ASIC comprising:
means for delaying a signal with a first fine grain resolution delay, said signal being input into logic cells and memory cells forming a core region of the Structured ASIC;
means for delaying said signal with a second coarse grain resolution delay, said signal being input into logic cells and memory cells forming a core region of the Structured ASIC;
said fine grain resolution delay being for a period of time less than the period of time said signal is capable of being delayed by said coarse resolution delay;
said first delaying means and said second delaying means being operatively connected to one another in series;
means for outputting a first thermometer coded control signal;
means for outputting a second thermometer coded control signal;
said first delaying means and said second delaying means have their delay means controlled by said first and second thermometer coded control signals, respectively;
wherein said DCDL controls the delay in a substantially glitch-free manner.
